(19) United States
(12) Patent Application Publication
(10) Pub. No.: US 2026/0013286 A1
(43) Pub. Date: Jan. 8, 2026

(54) MICROFLUIDIC TRANSFER SUBSTRATE, MICROFLUIDIC TRANSFER DEVICE, AND MICROFLUIDIC TRANSFER APPARATUS

(71) Applicant: HKC CORPORATION LIMITED, SHENZHEN (CN)

(72) Inventors: Zeyao LI, SHENZHEN (CN); Pei XU, SHENZHEN (CN)

(73) Assignee: HKC CORPORATION LIMITED, SHENZHEN (CN)

(21) Appl. No.: 19/245,264

(22) Filed: Jun. 21, 2025

(30) Foreign Application Priority Data
Jul. 2, 2024 (CN) 202410876325.X

(51) Int. Cl. H10H 29/03; H01L 21/66; H10H 29/01

(52) U.S. Cl. CPC H10H 29/03; H01L 22/10; H01L 22/22; H01L 22/26; H10H 29/012

(57) ABSTRACT

A microfluidic transfer substrate includes a plurality of pixel groups. Each pixel group includes at least three first pixel units, and the at least three first pixel units of each pixel group are arranged around a center point. One first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove. Each first pixel unit includes a thin film transistor, a microfluidic electrode layer, and a hydrophobic layer. A microfluidic transfer device and a microfluidic transfer apparatus are further provided.

### CROSS-REFERENCE TO RELATED APPLICATIONS

The present application claims priority to Chinese Patent Application No. 202410876325.X, entitled “MICROFLUIDIC TRANSFER SUBSTRATE, MICROFLUIDIC TRANSFER DEVICE, AND MICROFLUIDIC TRANSFER APPARATUS”, filed on Jul. 2, 2024, which is herein incorporated by reference in its entirety.

### TECHNICAL FIELD

The present disclosure relates to the technical field of display, and in particular to a microfluidic transfer substrate, a microfluidic transfer device, and a microfluidic transfer apparatus.

### BACKGROUND

With the advancement of light-emitting diode (LED) technology, micro-LED display technology is emerging as a revolutionary next-generation technology. The micro-LED is a display technology that miniaturizes and matrixes traditional LED structures, and achieves address control and individual driving of each pixel point through a driving backplane. Due to its superior performance in brightness, lifespan, contrast, response time, and other indicators compared to a liquid crystal display (LCD) and an organic light-emitting diode display (OLED), the micro-LED has been regarded by many manufacturers as the next-generation display technology, and the manufacturers have begun to actively layout the micro-LED.

However, a core technical challenge in the industrialization of the micro-LED is the mass transfer technology of micro-LED components. In related art, there is a problem of difficulty in transferring a large number of Micro LED components to the driving backplane.

### SUMMARY OF THE DISCLOSURE

A technical solution in the present disclosure is to provide a microfluidic transfer substrate. The microfluidic transfer substrate includes a plurality of pixel groups. Each pixel group includes at least three first pixel units, and the at least three first pixel units of each pixel group are arranged around a center point; one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove; and each first pixel unit includes a thin film transistor, a microfluidic electrode layer, and a hydrophobic layer.

In some embodiments, each pixel group includes four first pixel units, and the four first pixel units of the same pixel group are arranged to form a two-dimensional array of two rows and two columns.

In some embodiments, the plurality of pixel groups are arranged in the two-dimensional array, and the first microfluidic pixels of the plurality of pixel groups are located at the same position in the pixel groups.

In some embodiments, the microfluidic transfer substrate is configured to only transmit light at a position of the assembly groove.

In some embodiments, each first pixel unit includes a substrate, the thin film transistor, a first insulation layer, a planarization layer, the microfluidic electrode layer, a second insulation layer, and the hydrophobic layer arranged in sequence. The planarization layer is an opaque layer, the assembly groove penetrates through the opaque layer, and the microfluidic electrode layer is a transparent conductive layer or defines an opening corresponding to the assembly groove; or the microfluidic electrode layer is an opaque layer and defines the opening corresponding to the assembly groove.

In some embodiments, the planarization layer is a black material layer, the black material layer defines a through hole to expose a part of the first insulation layer, thereby forming the assembly groove. The microfluidic electrode layer, the second insulation layer, and the hydrophobic layer all cover a bottom surface and a side surface of the assembly groove; or the microfluidic electrode layer is only disposed on a surface of the black material layer away from the substrate and defines the opening corresponding to the assembly groove, and both the second insulation layer and the hydrophobic layer cover the bottom surface and the side surface of the assembly groove.

In some embodiments, the microfluidic transfer substrate includes a transfer zone and a liquid droplet generation zone surrounding the transfer zone, the plurality of pixel groups are disposed in the transfer area, and the liquid droplet generation zone is configured to generate and transport a liquid droplet containing a light-emitting element to the transfer zone.

In some embodiments, a plurality of second pixel units are disposed in the liquid droplet generation zone, the plurality of second pixel units have the same structure as the second microfluidic pixel, and all first pixel units in the transfer area and all second pixel units in the liquid droplet generation area are arranged in a two-dimensional array.

Another technical solution in the present disclosure is to provide a microfluidic transfer device including a microfluidic transfer substrate in any one of above embodiments, and a microfluidic control circuit. The microfluidic control circuit is electrically connected to the microfluidic transfer substrate. The microfluidic control circuit is configured to drive a liquid droplet containing a light-emitting element through the first pixel units of the pixel group to swing back and forth between the first microfluidic pixel and the second microfluidic pixels, or rotate around the center point, so as to assemble the light-emitting element into the assembly groove.

Yet another technical solution in the present disclosure is to provide a microfluidic transfer apparatus including a microfluidic transfer device in any one of above embodiments, a light source, and a camera. The light source is disposed on one side of the microfluidic transfer substrate and electrically connected to the microfluidic control circuit. The camera is disposed on the other side of the microfluidic transfer substrate and electrically connected to the microfluidic control circuit. The microfluidic control circuit is further configured to control the light source to emit light and irradiate the microfluidic transfer substrate, control the camera to capture an image of the microfluidic transfer substrate, and determine whether the light-emitting element is assembled in the assembly groove based on the image captured by the camera.

### BRIEF DESCRIPTION OF THE DRAWINGS

In order to more clearly illustrate the technical solutions in some embodiments of the present disclosure or in the related art, hereinafter, the accompanying drawings that are used in the description of some embodiments or the related art will be briefly described. Obviously, the accompanying drawings in the description below are merely the accompanying drawings in some embodiments of the present disclosure. For those of ordinary skill in the art, other accompanying drawings may be obtained based on these accompanying drawings without any creative efforts.

FIG. 1 is a structural block view of a microfluidic transfer device in the present disclosure.

FIG. 2 is a top structural schematic view of a microfluidic transfer substrate of the microfluidic transfer device of FIG. 1 in an embodiment.

FIG. 3 is a structural schematic view of a pixel group of the microfluidic transfer substrate of FIG. 2.

FIG. 4 is a cross-sectional structural schematic view of the microfluidic transfer substrate of FIG. 2.

FIG. 5 is a top structural schematic view of the microfluidic transfer substrate of FIG. 2 after assembling light-emitting elements.

FIG. 6 is a cross-sectional structural schematic view of the microfluidic transfer substrate of FIG. 2 after assembling the light-emitting elements.

FIG. 7 is a structural block view of a microfluidic transfer apparatus in the present disclosure.

FIG. 8 is a flowchart of a method for transferring the light-emitting elements in a first embodiment of the present disclosure.

FIG. 9 is a structural schematic view of the microfluidic transfer substrate corresponding to an operation at block S1 of FIG. 8 in an embodiment.

FIG. 10 is a structural schematic view of the microfluidic transfer substrate corresponding to the operation at block S1 of FIG. 8 in another embodiment.

FIG. 11 is a flowchart of an operation at block S2 in the method for transferring the light-emitting elements of FIG. 8.

FIG. 12 is a structural schematic view of a structure corresponding to an operation at block S21 of FIG. 11.

FIG. 13 is a structural schematic view of a structure corresponding to an operation at block S22 of FIG. 11.

FIG. 14 is a structural schematic view of a structure corresponding to an operation at block S3 of FIG. 8.

FIG. 15 is a structural schematic view of a structure corresponding to an operation at block S4 of FIG. 8.

FIG. 16 is a structural schematic view of the light-emitting element in an embodiment of the present disclosure.

FIG. 17 is a structural schematic view of the light-emitting element in another embodiment of the present disclosure.

FIG. 18 is a structural schematic view of the light-emitting element in yet another embodiment of the present disclosure.

FIG. 19 is a flowchart of a method for transferring the light-emitting elements in a second embodiment of the present disclosure.

FIG. 20 is a flowchart of a method for transferring the light-emitting elements in a third embodiment of the present disclosure.

### DETAILED DESCRIPTION

The technical solutions in some embodiments of the present disclosure may be clearly and completely described in conjunction with accompanying drawings in some embodiments of the present disclosure. Obviously, the described embodiments are only a part of the embodiments of the present disclosure, and not all embodiments. Based on the embodiments in the present disclosure, all other embodiments obtained by those of ordinary skill in the art without creative effort are within the scope of the present disclosure.

The terms “first”, “second”, and “third” in the present disclosure are only configured to describe and cannot be understood as indicating or implying relative importance or implicitly indicating the quantity of technical features indicated. Therefore, features that are defined as “first”, “second”, and “third” may explicitly or implicitly include at least one of these features. In the description of the present disclosure, “multiple” means at least two, such as two, three, etc., unless otherwise expressly and specifically qualified. In addition, the terms “including”, “comprising”, and “having”, as well as any variations of the terms “including”, “comprising”, and “having”, are intended to cover non-exclusive inclusions. For example, a process, method, system, product, or apparatus that includes a series of operations or units is not limited to the listed operations or units, but optionally includes operations or units that are not listed, or optionally includes other operations or units that are inherent to these processes, methods, products, or apparatus.

The reference to “embodiment” in the present disclosure means that, specific features, structures, or characteristics described in conjunction with some embodiments may be included in at least one embodiment of the present disclosure. The phrase appearing in various positions in the specification does not necessarily refer to the same embodiment, nor is it an independent or alternative embodiment that is mutually exclusive with other embodiments. Those of ordinary skill in the art explicitly and implicitly understand that the embodiments described in the present disclosure can be combined with other embodiments.

The present disclosure mainly provides a microfluidic transfer substrate, a microfluidic transfer device, and a microfluidic transfer apparatus, so as to solve the problem that it is difficult to achieve mass transfer of the light-emitting elements in related art.

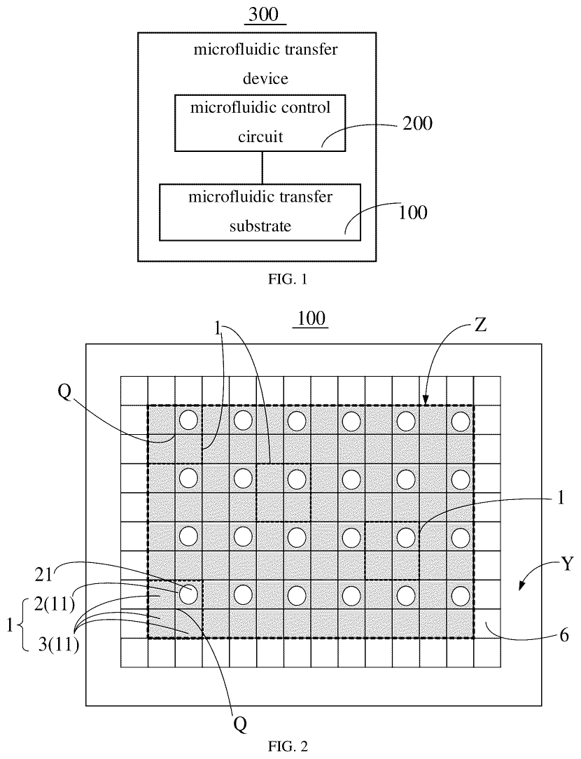

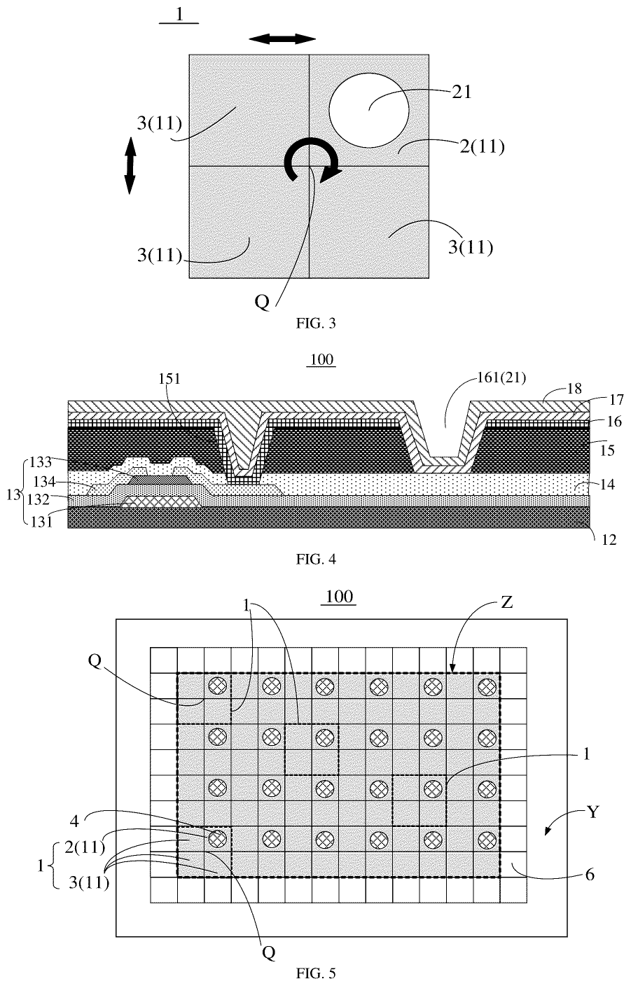

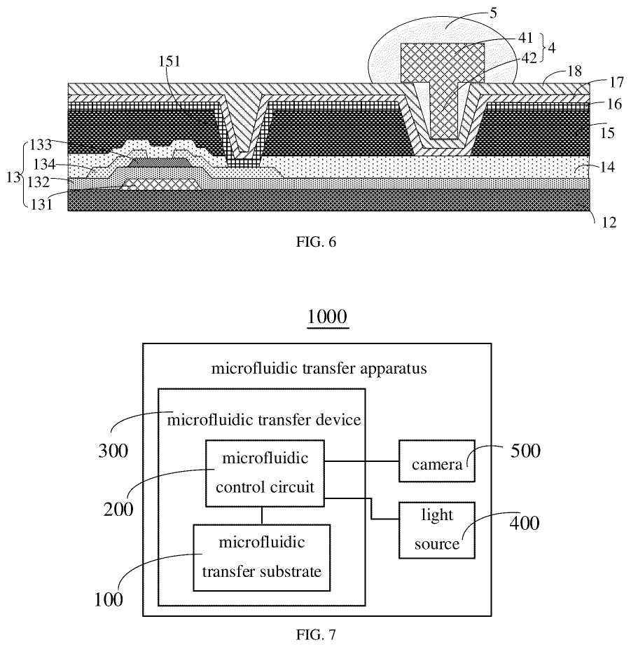

As illustrated in FIGS. 1 to 6, FIG. 1 is a structural block view of a microfluidic transfer device in the present disclosure. FIG. 2 is a top structural schematic view of a microfluidic transfer substrate of the microfluidic transfer device of FIG. 1 in an embodiment. FIG. 3 is a structural schematic view of a pixel group of the microfluidic transfer substrate of FIG. 2. FIG. 4 is a cross-sectional structural schematic view of the microfluidic transfer substrate of FIG. 2. FIG. 5 is a top structural schematic view of the microfluidic transfer substrate of FIG. 2 after assembling light-emitting elements. FIG. 6 is a cross-sectional structural schematic view of the microfluidic transfer substrate of FIG. 2 after assembling the light-emitting elements.

As illustrated in FIGS. 1 to 4, the present disclosure provides a microfluidic transfer device 300 that may be configured for mass transfer of light-emitting elements 4. As illustrated in FIG. 1, the microfluidic transfer device 300 includes a microfluidic transfer substrate 100 and a microfluidic control circuit 200, and the microfluidic control circuit 200 is electrically connected to the microfluidic transfer substrate 100.

In some embodiments, the microfluidic transfer substrate 100 includes multiple pixel groups 1, each pixel group includes at least three first pixel units 11 arranged around a center point Q. One first pixel unit 11 of each pixel group 1 serves as a first microfluidic pixel 2, and a surface of the first microfluidic pixel 2 defines an assembly groove 21. The other first pixel units 11 serve as second microfluidic pixels 3, and a surface of each of the second microfluidic pixels 3 does not define the assembly groove 21. Each first pixel unit 11 includes a thin film transistor 13, a microfluidic electrode layer 16, and a hydrophobic layer 18. Each pixel group 1 of the microfluidic transfer substrate 100 is disposed to include at least three first pixel units 11, and multiple first pixel units 11 are arranged around the center point Q. One first pixel unit 11 is the first microfluidic pixel 2 with the assembly groove 21. When using the microfluidic transfer substrate 100 to transfer the light-emitting element 4, it may be more convenient for the light-emitting element 4 to move inside at least three first pixel units 11 of each pixel group 1, and it is easier to assemble the light-emitting element 4 into the assembly groove 21 of the first microfluidic pixel 2, so as to achieve mass transfer of the light-emitting elements 4 using the microfluidic transfer substrate 100 in the present disclosure, solving the problem that it is difficult to achieve mass transfer of the light-emitting elements 4 in related art.

The microfluidic control circuit 200 is configured to drive the liquid droplet 5 containing the light-emitting element 4 through the first pixel units 11 of the pixel group 1 to swing back and forth between the first microfluidic pixel 2 and the second microfluidic pixels 3 or rotate around the center point Q, so as to assemble the light-emitting element 4 into the assembly groove 21. As illustrated in FIG. 3, the liquid droplet 5 containing the light-emitting element 4 is driven by the microfluidic control circuit 200 to swing or rotate between the first microfluidic pixel 2 and several second microfluidic pixels 3 in the pixel group 1, making it easier to assemble the light-emitting element 4 into the assembly groove 21 of the first microfluidic pixel 2 by the movement of the liquid droplet 5, which is conducive to improving the assembly yield and the assembly accuracy of the light-emitting elements 4.

As illustrated in FIGS. 2 and 3, in some embodiments, each pixel group 1 includes four first pixel units 11, and the four first pixel units 11 of the same pixel group 1 are arranged to form a two-dimensional array of two rows and two columns. That is, each pixel group 1 includes one first microfluidic pixel 2 and three second microfluidic pixels 3. In some embodiments, the first pixel unit 11 is rectangular in shape.

In some embodiments, each pixel group 1 may also include any number of first pixel units 11, such as three, five, six, etc. The multiple first pixel units 11 of each pixel group 1 may not be distributed in an array. The first pixel unit 11 may also be in any shape, such as a circle, a diamond, a triangle, a pentagon, a hexagon, etc. A specific distribution form of the multiple first pixel units 11 of the pixel group 1 is not limited in the present disclosure and may be designed as needed, as long as the multiple first pixel units 11 of the same pixel group 1 may be distributed around the center point Q, so as to facilitate the assembly of the light-emitting element 4 into the assembly groove 21 of the first microfluidic pixel 2.

As illustrated in FIGS. 2 and 3, in some embodiments, the multiple pixel groups 1 are arranged in a two-dimensional array, and the first microfluidic pixels 2 of each pixel group 1 are located at the same position in the pixel group 1. The first microfluidic pixels 2 of the multiple pixel groups 1 are located at the same position in the pixel group 1, which means that the position of the first microfluidic pixel 2 in each pixel group 1 is the same. In some embodiments, each pixel group 1 includes four first pixel units 11, the four first pixel units 11 are arranged to form the two-dimensional array of two rows and two columns, and the first microfluidic pixel 2 of each pixel group 1 is located in the first row and the second column. The multiple pixel groups 1 are distributed in the two-dimensional array, and the first microfluidic pixel 2 of each pixel group 1 is located at the same position in the pixel group 1. Therefore, it is easier to drive the liquid droplet 5 containing the light-emitting element 4 to move or rotate in the pixel group 1, and adjacent pixel groups 1 may not affect or interfere with each other, which is more conducive to driving the liquid droplet 5 to move, so as to assemble the light-emitting element 4 into the assembly groove 21 of the first microfluidic pixel 2.

In some embodiments, the first microfluidic pixel 2 of each pixel group 1 may be located in the first row and first column of the pixel group 1, or in the second row and first column, or in the second row and second column. Alternatively, the positions of the first microfluidic pixels 2 of the multiple pixel groups 1 may be different. In some embodiments, the first microfluidic pixel 2 of the first pixel group 1 of the first row of pixel groups 1 may be located in the first row and first column of the pixel group 1, and the first microfluidic pixel 2 of the second pixel group 1 of the first row of pixel groups 1 may be located in the first row and the second column of the pixel group 1. The first microfluidic pixels 2 of the multiple pixel groups 1 may be randomly distributed, as long as it may ensure that the microfluidic control circuit 200 may drive the liquid droplet 5 containing the light-emitting element 4 to rotate around the center point Q in the pixel group 1 or swing in the pixel group 1 through the first pixel units 11 of the pixel group 1, so that the light-emitting element 4 may be assembled into the assembly groove 21 of the first microfluidic pixel 2.

In some embodiments, the multiple pixel groups 1 may not be distributed in the two-dimensional array, and may be randomly distributed. In some embodiments, the multiple pixel groups 1 of the microfluidic transfer substrate 100 may be spaced apart from each other and surrounded in any shape, such as, a circular ring, a triangle, a rectangular ring, or a pentagon, etc. The multiple pixel groups 1 of the microfluidic transfer substrate 100 may also be spaced apart from each other in a discrete point distribution on the microfluidic transfer substrate 100, which may be designed as needed and may not be limited in the present disclosure.

As illustrated in FIGS. 2 and 3, in some embodiments, the microfluidic transfer substrate 100 includes a transfer zone Z and a liquid droplet generation zone Y surrounding the transfer zone Z. The multiple pixel groups 1 are disposed in the transfer zone Z, and the liquid droplet generation zone Y is configured to generate and transport the liquid droplets 5 containing the light-emitting elements 4 to the transfer zone Z. That is, the liquid droplet 5 containing the light-emitting element 4 is first generated in the liquid droplet generation zone Y, and then transported from the liquid droplet generation zone Y to the pixel group 1 in the transfer zone Z. The liquid droplet 5 moves, so as to complete the assembly of the light-emitting element 4. As illustrated in FIG. 3, in some embodiments, the multiple two-dimensional array distributed pixel groups 1 in the transfer zone Z form a rectangular transfer zone Z, and the liquid droplet generation zone Y is arranged around the periphery of the transfer zone Z. That is, the liquid droplet generation zone Y is arranged in a rectangular ring shape.

In some embodiments, the transfer zone Z may not be rectangular, and the liquid droplet generation zone Y may be disposed at any position in the transfer zone Z. That is, the liquid droplet generation zone Y may not be disposed around the transfer zone Z. In some embodiments, the liquid droplet generation zone Y may be disposed only on one side or both sides of the transfer zone Z, as long as it may ensure that the liquid droplet generation zone Y may generate the liquid droplets 5 containing the light-emitting elements 4 and may be communicated with the transfer zone Z, so as to transport the liquid droplets 5 containing the light-emitting elements 4 to the transfer zone Z, which may not be limited in the present disclosure.

In some embodiments, the microfluidic transfer substrate 100 may not have the liquid droplet generation zone Y, that is, the microfluidic transfer substrate 100 may only have the transfer zone Z. The liquid droplet 5 containing the light-emitting element 4 may be directly generated and transported to the area where different pixel groups I are located in the transfer zone Z by disposing other structural components.

In some embodiments, multiple liquid droplets 5 containing the light-emitting elements 4 may be uniformly generated by mixing a solution (not illustrated in figures) and the light-emitting elements 4 in the liquid droplet generation zone Y, and then the liquid droplets 5 containing the light-emitting elements 4 may be transported from the liquid droplet generation zone Y to the pixel groups 1 in the transfer zone Z.

In some embodiments, a specific structural component (not illustrated in figures) may be disposed to directly generate the liquid droplet 5 containing the light-emitting element 4 and directly transport the liquid droplet 5 containing the light-emitting element 4 to each pixel group 1. That is, the liquid droplet generation zone Y may be omitted, and the liquid droplet 5 containing the light-emitting element 4 may be directly generated and transported by the structural component. In some embodiments, the structural component may be a print head, and the print head may be located above the microfluidic transfer substrate 100, and may move between regions corresponding to different pixel groups 1. The liquid droplet 5 containing the light-emitting element 4 may be directly dropped onto areas of the microfluidic transfer substrate 100 where different pixel groups 11 are located, so that each pixel group 1 contains one liquid droplet 5 containing the light-emitting element 4, which facilitates the assembly of the light-emitting elements 4, thereby facilitating the mass transfer of the light-emitting elements 4.

As illustrated in FIGS. 2 and 3, in some embodiments, the liquid droplet generation zone Y includes multiple second pixel units 6, and a structure of the second pixel unit 6 is the same as that of the second microfluidic pixel 3. That is, a surface of the second pixel unit 6 does not define the assembly groove 21. All the first pixel units 11 in the transfer zone Z and all the second pixel units 6 in the liquid droplet generation zone Y are arranged in the two-dimensional array. That is, the multiple second pixel units 6 in the liquid droplet generation zone Y and the multiple first pixel units 11 in the transfer zone Z together form the two-dimensional array. The multiple second pixel units 6 in the liquid droplet generation zone Y are located in the row or the column where the first pixel units 11 are located in the transfer zone Z. By setting the multiple second pixel units 6 in the liquid droplet generation zone Y, and the second pixel units 6 and all the first pixel units 11 in the transfer zone Z are distributed together in the two-dimensional array, when the liquid droplet 5 containing the light-emitting element 4 generated in the liquid droplet generation zone Y is transported to the pixel group 1 in the transfer zone Z, the second pixel unit 6 may be configured as a transport channel for the liquid droplet 5, which is more convenient for the microfluidic control circuit 200 to drive the transportation of the liquid droplet 5 containing the light-emitting element 4 to the pixel group 1. It is conducive to shortening a transport path of the liquid droplet 5, improving the transport efficiency of the liquid droplet 5, thereby improving the assembly efficiency of the light-emitting element 4.

In some embodiments, the liquid droplet generation zone Y may not have the second pixel unit 6, the liquid droplet generation zone Y may be set only around the transfer zone Z, and the liquid droplet 5 containing the light-emitting element 4 is only generated in the liquid droplet generation zone Y. The liquid droplets 5 containing the light-emitting elements 4 generated in the liquid droplet generation zone Y may move in any direction or trajectory in the liquid droplet generation zone Y, as long as the liquid droplets 5 containing the light-emitting elements 4 may be transported from the liquid droplet generation zone Y to the transfer zone Z.

In some embodiments, as illustrated in FIG. 2, the multiple pixel groups 1 in the transfer zone Z of the microfluidic transfer substrate 100 are distributed in the two-dimensional array and form a rectangular transfer zone Z. The liquid droplet generation zone Y is set around the rectangular transfer zone Z. The liquid droplet 5 containing the light-emitting element 4 generated in the liquid droplet generation zone Y may enter the transfer zone Z from a direction perpendicular to any one or more of four sides of the transfer zone Z. Therefore, the liquid droplet 5 containing the light-emitting element 4 in the liquid droplet generation zone Y is transported to the area where the pixel group 1 is located in the transfer zone Z.

In some embodiments, when the multiple pixel groups 1 in the transfer zone Z are randomly distributed, the liquid droplet 5 containing the light-emitting element 4 in the liquid droplet generation zone Y may also enter the area where the pixel group 1 is located from any other directions, which may be designed as needed.

In some embodiments, as illustrated in FIG. 4, each of the first pixel unit 11 and the second pixel unit 6 includes a substrate 12, a thin film transistor (TFT) 13, a first insulating layer 14, a planarization layer 15, a microfluidic electrode layer 16, a second insulating layer 17, and a hydrophobic layer 18 arranged in sequence. The planarization layer 15 is an opaque layer, and the assembly groove 21 penetrates through the opaque layer.

In some embodiments, as illustrated in FIG. 4, the thin film transistor 13 is disposed on the substrate 12. The thin film transistor 13 includes a gate metal layer 131, a gate insulation layer 132, an active layer 133, and a source drain metal layer 134 stacked in sequence. The gate insulation layer 132 is disposed on a side of the gate metal layer 131 away from the substrate 12 and covers the gate metal layer 131 and the substrate 12. The active layer 133 is disposed at a position corresponding to the gate metal layer 131 and partially covers the gate insulation layer 132. The source drain metal layer 134 is disposed on a side of the active layer 133 away from the substrate 12 and covers a part of the active layer 133 and a part of the gate insulation layer 132. The source drain metal layer 134 includes a source electrode (not labeled in the figure) and a drain electrode (not labeled in the figure) arranged at intervals. A part of the active layer 133 is exposed at a position where the drain electrode and source electrode are spaced apart from each other. The first insulation layer 14 is located on a side of the source drain metal layer 134 away from the substrate 12 and covers the source drain metal layer 134, the active layer 133, and the gate insulation layer 132. The planarization layer 15, the microfluidic electrode layer 16, the second insulation layer 17, and the hydrophobic layer 18 are disposed on a surface of the first insulation layer 14 away from the substrate 12. The planarization layer 15 defines a via hole 151 spaced apart from the assembly groove 21, the via hole 151 sequentially penetrates through the planarization layer 15 and the first insulation layer 14 and expose a part of the source drain metal layer 134. The microfluidic electrode layer 16 covers the sidewalls of the via hole 151 and is in contact with the source drain metal layer 134.

In some embodiments, as illustrated in FIG. 4, the planarization layer 15 is a black material layer, and the black material layer defines a through hole to expose a part of the first insulation layer 14, thereby forming the assembly groove 21.

In some embodiments, the microfluidic electrode layer 16 is a transparent conductive layer. The microfluidic electrode layer 16 may be a single continuous layer, or the microfluidic electrode layer 16 defines an opening 161 corresponding to the assembly groove 21. In some embodiments, the microfluidic electrode layer 16 may be a transparent conductive layer of indium tin oxide (ITO). As illustrated in FIG. 4, in some embodiments, the microfluidic electrode layer 16 defines the opening 161 at a position corresponding to the assembly groove 21. That is, the microfluidic electrode layer 16 is not disposed inside the assembly groove 21, and the opening 161 of the microfluidic electrode layer 16 directly exposes the assembly groove 21 and a part of the first insulation layer 14. In some embodiments, since the microfluidic electrode layer 16 is the transparent conductive layer, light may penetrate through the microfluidic electrode layer 16. Therefore, the microfluidic electrode layer 16 may not define the opening 161 at the position corresponding to the assembly groove 21, and the planarization layer 15 and the side surface and the bottom surface of the assembly groove 21 may be directly covered by the microfluidic electrode layer 16.

In some embodiments, the microfluidic electrode layer 16 may be the opaque layer, and the microfluidic electrode layer 16 defines the opening 161 at the position corresponding to the assembly groove 21. Due to the opaque nature of the microfluidic electrode layer 16, the opening 161 is defined at the position of the microfluidic electrode layer 16 corresponding to the assembly groove 21, so that the assembly groove 21 is exposed and the position of the assembly groove 21 may still transmit light.

That is, in some embodiments, the microfluidic electrode layer 16 is the transparent conductive layer, and the microfluidic electrode layer 16, the second insulation layer 17, and the hydrophobic layer 18 may all cover the bottom surface and the side surface of the assembly groove 21. In some embodiments, as illustrated in FIG. 4, the microfluidic electrode layer 16 may only be disposed on the surface of the black planarization layer 15 away from the substrate 12 and defines the opening 161 corresponding to the assembly groove 21, and the second insulation layer 17 and the hydrophobic layer 18 may all cover the bottom surface and the side surface of the assembly groove 21.

In the present embodiment, the microfluidic transfer substrate 100 only transmits light at the position of the assembly groove 21. When the microfluidic control circuit 200 drives the liquid droplet 5 containing the light-emitting element 4 to assemble the light-emitting element 4 into the assembly groove 21 of the first microfluidic pixel 2, the assembly groove 21 is filled with the light-emitting element 4. When the light irradiates the microfluidic transfer substrate 100, the light passing through the assembly groove 21 may be greatly reduced, and even the position of the assembly groove 21 may no longer transmit light. Therefore, the microfluidic transfer substrate 100 may be irradiated by a light source 400 or the like to detect or determine whether the light-emitting element 4 is assembled in the assembly groove 21, and accordingly the position of the first microfluidic pixel 2 that is not provided with the light-emitting element 4 may be screened out for subsequent operations, such as secondary assembly.

In some embodiments, the microfluidic control circuit 200 is configured to first control the movement of the liquid droplet 5 containing the light-emitting element 4 on the microfluidic transfer substrate 100, so that the liquid droplet 5 containing the light-emitting element 4 is disposed in the area where each pixel group 1 is located. The microfluidic control circuit 200 is configured to then simultaneously drive the liquid droplet 5 containing the light-emitting element 4 in the area where each pixel group 1 is located to swing back and forth between the first microfluidic pixel 2 and the second microfluidic pixels 3 or rotate around the center point Q, so as to assemble the light-emitting element 4 into the assembly groove 21.

That is, the microfluidic control circuit 200 first controls the liquid droplets 5 containing the light-emitting elements 4 generated in the liquid droplet generation zone Y to be transported from the liquid droplet generation zone Y to the multiple pixel groups 1 in the transfer zone Z. In some embodiments, the microfluidic control circuit 200 first controls the liquid droplets 5 containing the light-emitting elements 4 in the liquid droplet generation zone Y to be transported from the liquid droplet generation zone Y to the multiple pixel groups 1 in the transfer zone Z, and the number of the liquid droplets 5 containing the light-emitting elements 4 is equal to the number of the pixel groups 1 in the transfer zone Z (that is, the number of the liquid droplets 5 containing the light-emitting elements 4 is equal to the number of the assembly grooves of the first microfluidic pixels 2 in the transfer zone Z). Therefore, each pixel group 1 in the transfer zone Z of the microfluidic transfer substrate 100 has a corresponding liquid droplet 5 containing the light-emitting element 4. Then, the microfluidic control circuit 200 simultaneously drives the liquid droplets 5 containing the light-emitting elements 4 that have already reached the multiple different pixel groups 1 to swing back and forth between the first microfluidic pixel 2 and the multiple second microfluidic pixels 3 in the corresponding pixel group 1, or rotate around the center point Q of the corresponding pixel group 1. Therefore, each of the light-emitting elements 4 of the multiple pixel groups 1 in the transfer zone Z may be assembled into the assembly groove 21 of the corresponding first microfluidic pixel 2. That is, the multiple liquid droplets 5 containing the light-emitting elements 4 generated in the liquid droplet generation zone Y are first uniformly transported to different pixel groups 1 in the transfer zone Z, and then assembled uniformly.

The time for uniformly transporting the liquid droplets 5 containing the light-emitting elements 4 to the transfer zone Z, and the time for uniformly assembling the light-emitting elements 4 in the pixel groups 1 of the transfer zone Z, are staggered by control of the microfluidic control circuit 200. It may prevent the situation where some liquid droplets 5 containing the light-emitting elements 4 have already arrived at the pixel groups 1 and started the assembly process, while other liquid droplets 5 containing the light-emitting elements 4 are still being transported from the liquid droplet generation zone Y to partial pixel groups 1 in the transfer zone Z. That is, transportation and assembly are occurring simultaneously, and the motion trajectory during the transportation and the motion trajectory in the assembly partially overlap with each other, which causes the liquid droplets 5 containing the light-emitting elements 4 that are moving towards the pixel groups 1 in the transfer zone Z to interfere with the liquid droplets 5 containing the light-emitting elements 4 that are swinging back and forth or rotating around the center point Q in the pixel group 1. This interference may prevent the liquid droplets 5 containing the light-emitting elements 4 from being transported into the pixel groups 1, or this interference may prevent the liquid droplets 5 containing the light-emitting elements 4 in the pixel groups 1 from moving to assemble the light-emitting elements 4 into the assembly grooves 21 to. By avoiding this interference, it is conducive to improving the transportation efficiency of the liquid droplets 5 containing the light-emitting elements 4 and the assembly efficiency of the light-emitting elements 4, thereby enhancing the overall assembly yield.

In some embodiments, the microfluidic control circuit 200 may also be configured to first control some the liquid droplets 5 containing the light-emitting elements 4 to move on the microfluidic transfer substrate 100, so as to transport the liquid droplets 5 containing the light-emitting elements 4 to the area where some pixel groups 1 are located, that is, the liquid droplets 5 containing the light-emitting elements 4 in some pixel groups 1. Then, the microfluidic control circuit 200 may be configured to simultaneously drive the liquid droplets 5 containing the light-emitting elements 4 in the pixel groups 1 that already have the liquid droplets 5 containing the light-emitting elements 4 to swing back and forth between the first microfluidic pixel 2 and the second microfluidic pixels 3 or rotate around the center point Q, so as to assemble the light-emitting elements 4 into the assembly grooves 21 of the first microfluidic pixels 2. And the microfluidic control circuit 200 simultaneously controls other liquid droplets 5 containing the light-emitting elements 4 to move on the microfluidic transfer substrate 100, so that the liquid droplets 5 containing the light-emitting elements 4 are transported to the areas where the pixel groups 1 are located, which previously do not contain such liquid droplets 5 containing the light-emitting elements 4. Therefore, the liquid droplets 5 containing the light-emitting elements 4 are disposed in theses pixel groups 1. Then, the liquid droplets 5 containing the light-emitting elements 4 in these pixel groups 1 are driven to swing back and forth between the first microfluidic pixel 2 and the second microfluidic pixels 3 or rotate around the center point Q, so as to assemble the light-emitting elements 4 into the assembly grooves 21 of the first microfluidic pixels 2, completing the assembly of the light-emitting elements 4. That is, the process of transporting the liquid droplets 5 containing the light-emitting elements 4 into the pixel groups 1 in transfer zone Z, and the process of moving the liquid droplets 5 containing the light-emitting elements 4 in the pixel group 1, may be synchronized, as long as they do not interfere with each other.

As illustrated in FIGS. 5 and 6, after transporting the liquid droplets 5 containing the light-emitting elements 4 to the pixel groups 1 in the transfer zone Z, and assembling the light-emitting elements 4 into the assembly grooves 21 of the first microfluidic pixels 2, the structure of the microfluidic transfer substrate 100 is illustrated in FIGS. 5 and 6.

As illustrated in FIG. 6, in some embodiments, the light-emitting element 4 is a light-emitting diode (LED), the light-emitting diode includes a body part 41 and a protruding part 42 protruding from the body part 41. A width of the protruding part 42 is less than that of the assembly groove 21, and a width of the body part 41 is greater than that of the assembly groove 21. After assembling the light-emitting element 4 into the assembly groove 21, the protruding part 42 is inserted into the assembly groove 21, and the body part 41 protrudes from the assembly groove 21. The width of the protruding part 42 of the light-emitting element 4 is set to be less than that of the assembly groove 21, and the width of the body part 41 is set to be greater than that of the assembly groove 21. Therefore, the protruding part 42 may be matched with the assembly groove 21, and the assembly of the light-emitting element 4 in the assembly groove 21 may be achieved by inserting the protruding part 42 into the assembly groove 21, which is more conducive to improving the assembly efficiency. After assembling the protruding part 42 into the assembly groove 21, the light-emitting element 4 is not easily detached from the assembly groove 21, which is conducive to improving the assembly yield.

In the microfluidic transfer device 300 in the present disclosure, the liquid droplet 5 containing the light-emitting element 4 may be driven by the microfluidic control circuit 200 to be transported to the pixel group 1 in the transfer zone Z. The liquid droplet 5 containing the light-emitting element 4 may be driven by the microfluidic control circuit 200 through the first pixel units 11 of the pixel group 1 to swing back and forth between the first microfluidic pixel 2 and the second microfluidic pixels 3 or rotate around the center point Q, so as to assemble the light-emitting element 4 into the assembly groove 21. The movement mode of the liquid droplet 5 driven by the microfluidic control circuit 200 makes it easier to assemble the light-emitting element 4 into the assembly groove 21 of the first microfluidic pixel 2, which is more conducive to improving the assembly yield and the assembly accuracy of the light-emitting element 4. Furthermore, it is easier to achieve mass transfer of the light-emitting elements 4 through the microfluidic transfer device 300, solving the problem that it is difficult to achieve mass transfer of the light-emitting elements 4 in related art.

As illustrated in FIG. 7, FIG. 7 is a structural block view of a microfluidic transfer apparatus in the present disclosure.

As illustrated in FIG. 7, the present disclosure further provides a microfluidic transfer apparatus 1000, which may be configured to achieve mass transfer of the light-emitting elements 4. In some embodiments, the microfluidic transfer apparatus 1000 includes the microfluidic transfer device 300, the light source 400, and a camera 500. The microfluidic transfer device 300 may be any one of the microfluidic transfer devices 300 in the above embodiments. The light source 400 is disposed on one side of the microfluidic transfer substrate 100 of the microfluidic transfer device 300 and electrically connected to the microfluidic control circuit 200 of the microfluidic transfer device 300. The camera 500 is disposed on the other side of the microfluidic transfer substrate 100 and electrically connected to the microfluidic control circuit 200. In some embodiments, the camera 500 is a high-resolution camera 500.

In some embodiments, the microfluidic control circuit 200 is further configured to control the light source 400 to emit light and irradiate the microfluidic transfer substrate 100, control the camera 500 to capture an image of the microfluidic transfer substrate 100, and determine whether the light-emitting element 4 is assembled in the assembly groove 21 based on the image captured by the camera 500. In some embodiments, since the planarization layer 15 of the present disclosure is the opaque layer, when the light-emitting element 4 is assembled in the assembly groove 21 of the first microfluidic pixel 2 of the microfluidic transfer substrate 100, and the microfluidic control circuit 200 controls the light source 400 to emit light and irradiate the microfluidic transfer substrate 100, the light passing through the assembly groove 21 may be greatly reduced or even the position of the assembly groove 21 may no longer be transparent or transmit light. When some assembly grooves 21 are not provided with the light-emitting elements 4, and the light source 400 emits light and irradiates the microfluidic transfer substrate 100, the light passing through the assembly groove 21 without the light-emitting element 4 is still sufficient. The microfluidic control circuit 200 controls the camera 500 to captured the image of the microfluidic transfer substrate 100. Based on the image, it may be clearly determined which first microfluidic pixels 2 of the multiple pixel groups 1 on the microfluidic transfer substrate 100 have not been assembled with the light-emitting element 4 into their assembly grooves 21, and which first microfluidic pixels 2 have already had the light-emitting elements 4 assembled into their assembly grooves 21. It may determine the assembly yield of the light-emitting elements 4 on the microfluidic transfer substrate 100, so that when the assembly yield does not meet the standard, subsequent operations such as secondary assembly may be performed on the first microfluidic pixel 2 that has not been assembled with the light-emitting element 4. In some embodiments, the microfluidic control circuit 200 may control and drive the liquid droplet 5 containing the light-emitting element 4 to supplement the assembly of the light-emitting element 4 into the assembly groove 21 that is not provided with the light-emitting element 4.

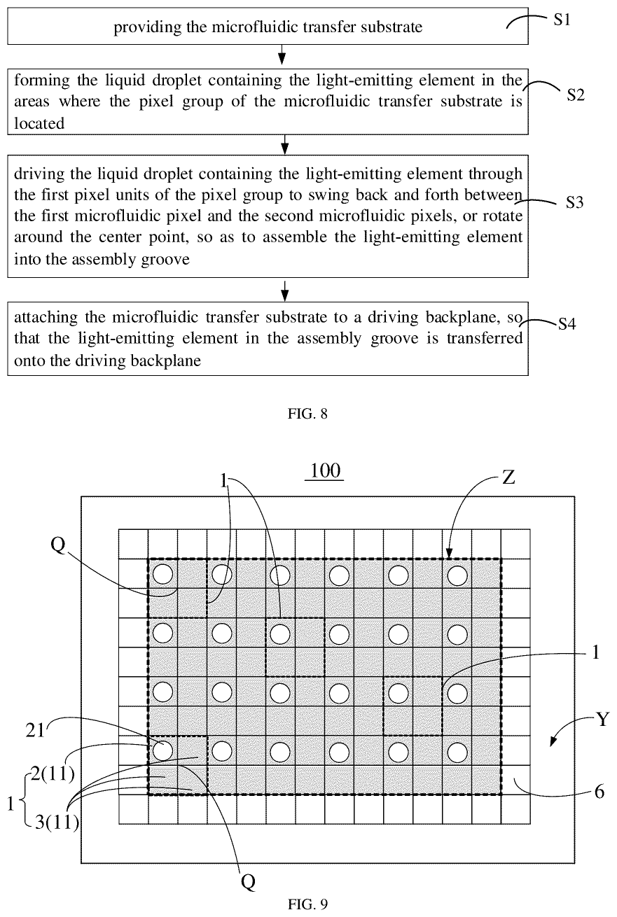

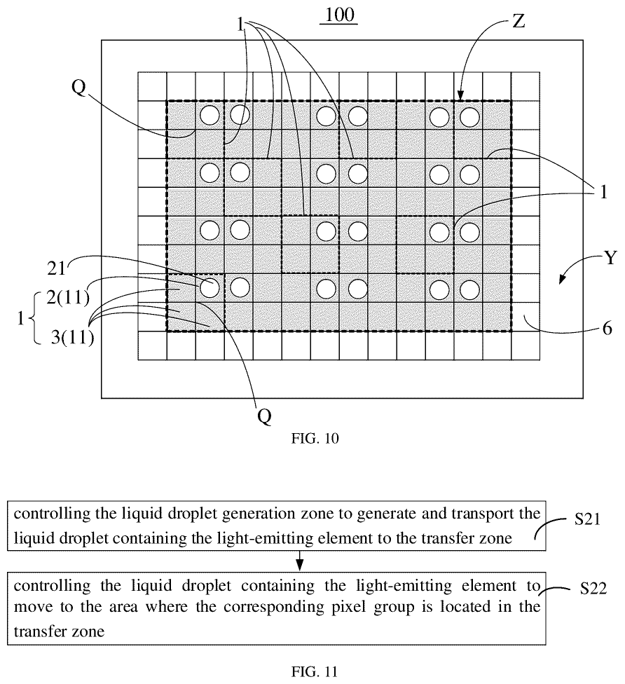

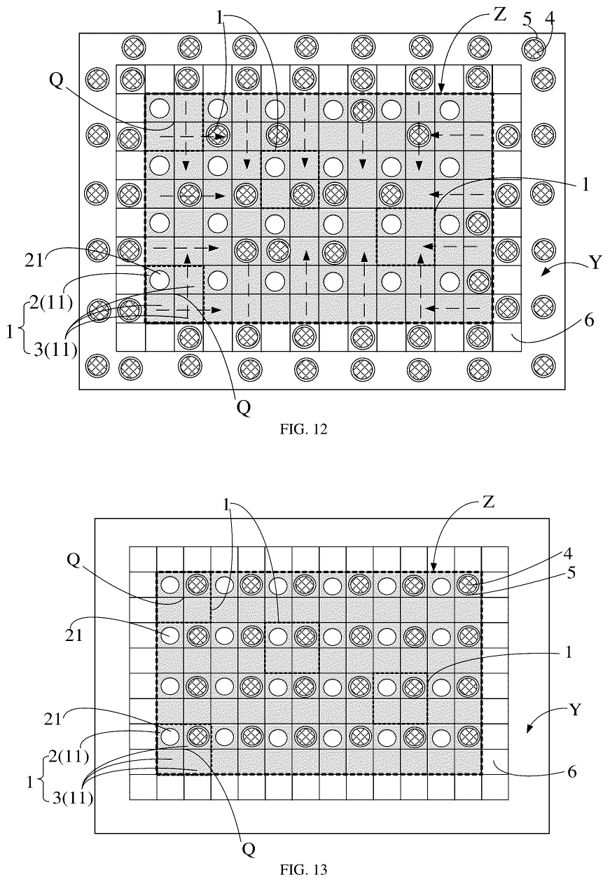

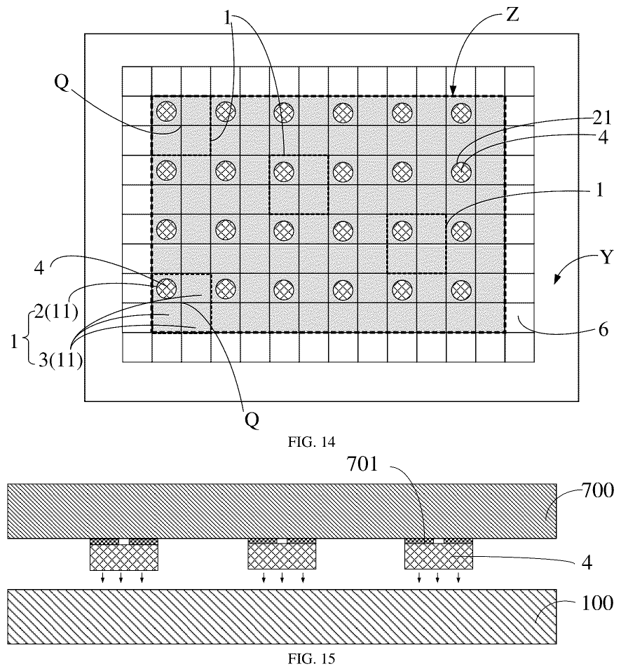

As illustrated in FIGS. 8 to 15, FIG. 8 is a flowchart of a method for transferring the light-emitting elements in a first embodiment of the present disclosure. FIG. 9 is a structural schematic view of the microfluidic transfer substrate corresponding to an operation at block S1 of FIG. 8 in an embodiment. FIG. 10 is a structural schematic view of the microfluidic transfer substrate corresponding to the operation at block S1 of FIG. 8 in another embodiment. FIG. 11 is a flowchart of an operation at block S2 in the method for transferring the light-emitting elements of FIG. 8. FIG. 12 is a structural schematic view of a structure corresponding to an operation at block S21 of FIG. 11. FIG. 13 is a structural schematic view of a structure corresponding to an operation at block S22 of FIG. 11. FIG. 14 is a structural schematic view of a structure corresponding to an operation at block S3 of FIG. 8. FIG. 15 is a structural schematic view of a structure corresponding to an operation at block S4 of FIG. 8.

As illustrated in FIG. 8, the present disclosure also provides a method for transferring the light-emitting elements 4, which is configured to achieve mass transfer of the light-emitting elements 4. In some embodiments, the transfer method of the light-emitting element 4 includes the following operations.

At block S1, the transfer method of the light-emitting element 4 may include providing the microfluidic transfer substrate 100.

In some embodiments, the microfluidic transfer substrate 100 is provided, as illustrated in FIG. 9. The microfluidic transfer substrate 100 includes the multiple pixel groups 1, and each pixel group 1 includes at least three first pixel units 11. The first pixel units 11 of the pixel group 1 are arranged around the center point Q, and one first pixel unit 11 of each pixel group 1 serves as the first microfluidic pixel 2. The surface of the first microfluidic pixel 2 defines the assembly groove 21, and the other first pixel units 11 serve as the second microfluidic pixels 3, and the surface of each the second microfluidic pixel 3 does not define the assembly groove 21.

In some embodiments, the structure of the microfluidic transfer substrate 100 is similar or identical to that of the microfluidic transfer substrate 100 of the microfluidic transfer device 300 in any one of the above embodiments, and they may achieve the same technical effects, which may not be repeated here.

At block S2, the transfer method of the light-emitting element 4 may include forming the liquid droplet 5 containing the light-emitting element 4 in the areas where the pixel group 1 of the microfluidic transfer substrate 100 is located.

In some embodiments, the microfluidic transfer substrate 100 includes the multiple pixel groups 1, and the liquid droplets 5 containing the light-emitting elements 4 are formed in the areas where the pixel groups 1 of the microfluidic transfer substrate 100 are located. The light-emitting elements 4 may be light-emitting diodes or micro light-emitting diodes.

In some embodiments, the operation at block of forming the liquid droplet 5 containing the light-emitting element 4 in the areas where the pixel group 1 of the microfluidic transfer substrate 100 is located, as described in the operation at block S2, includes:
forming the liquid droplet 5 containing the light-emitting element 4 in the area where each pixel group 1 of the microfluidic transfer substrate 100 is located.

In some embodiments, the liquid droplet 5 containing the light-emitting element 4 is formed in the area where each pixel group 1 of the microfluidic transfer substrate 100 is located. That is, each pixel group 1 contains the liquid droplet 5 containing the light-emitting element 4. The liquid droplet 5 containing the light-emitting element 4 is formed in the area where each pixel group 1 of the microfluidic transfer substrate 100 is located, which is conducive to improving the assembly yield of the light-emitting elements 4 and thus improving the transfer efficiency of the mass transfer of the light-emitting elements 4.

In some embodiments, the area where some pixel groups 1 of the microfluidic transfer substrate 100 are located may not have the liquid droplets 5 containing the light-emitting elements 4. That is, only some pixel groups 1 of the microfluidic transfer substrate 100 have the liquid droplets 5 containing the light-emitting elements 4.

In some embodiments, as illustrated in FIG. 9, in some embodiments, the microfluidic transfer substrate 100 has the transfer zone Z and the liquid droplet generation zone Y adjacent to the transfer zone Z. The multiple pixel groups 1 of the microfluidic transfer substrate 100 are located in the transfer zone Z, and the liquid droplet generation zone Y is configured to generate the liquid droplets 5 containing the light-emitting elements 4. Since the liquid droplet generation zone Y is adjacent to the transfer zone Z, the liquid droplets 5 containing the light-emitting elements 4 generated in the liquid droplet generation zone Y may be transported to the transfer zone Z.

As illustrated in FIG. 11, in some embodiments, the operation of forming the liquid droplet 5 containing the light-emitting element 4 in the area where each pixel group 1 of the microfluidic transfer substrate 100 is located, includes the following operations.

At block S21, the operation of forming the liquid droplet 5 containing the light-emitting element 4 in the area where each pixel group 1 of the microfluidic transfer substrate 100 is located, may include: controlling the liquid droplet generation zone Y to generate and transport the liquid droplet 5 containing the light-emitting element 4 to the transfer zone Z.

In some embodiments, as illustrated in FIG. 12, the liquid droplet generation zone Y is controlled to generate the liquid droplets 5 containing the light-emitting elements 4, and transport the liquid droplets 5 containing the light-emitting elements 4 to the transfer zone Z, so that there are multiple liquid droplets 5 containing the light-emitting elements 4 in the transfer zone Z. During this operation, the liquid droplet 5 containing the light-emitting element 4 that is controlled to be transported from the liquid droplet generation zone Y to the transfer zone Z may be located at any position in the transfer zone Z, as illustrated in FIG. 12. After this operation is completed, the multiple liquid droplets 5 containing the light-emitting elements 4 in the transfer zone Z may be distributed randomly.

At block S22, the operation of forming the liquid droplet 5 containing the light-emitting element 4 in the area where each pixel group 1 of the microfluidic transfer substrate 100 is located, may include: controlling the liquid droplet 5 containing the light-emitting element 4 to move to the area where the corresponding pixel group 1 is located in the transfer zone Z.

In some embodiments, in the operation at block S21, after the liquid droplet 5 containing the light-emitting element 4 has been transported to the transfer zone Z, the liquid droplet 5 containing the light-emitting element 4 is controlled to move to the corresponding area where the pixel group 1 is located in the transfer zone Z, as illustrated in FIG. 13, so that each pixel group 1 in the transfer zone Z has the liquid droplet 5 containing the light-emitting element 4.

That is, in the operation at block S21, the liquid droplets 5 containing the light-emitting elements 4 generated in the liquid droplet generation zone Y are uniformly transported to the transfer zone Z. During this process, the liquid droplets 5 containing the light-emitting elements 4 may be distributed randomly in the transfer zone Z, and it is not necessary to ensure that the liquid droplet 5 containing the light-emitting element 4 is located in the area where each pixel group 1 is located. In the operation at block S22, the multiple liquid droplets 5 containing the light-emitting elements 4 that have already been transported to the transfer zone Z are redistributed, and the multiple liquid droplets 5 containing the light-emitting elements 4 in the transfer zone Z are controlled to move in the transfer zone Z, so that the liquid droplet 5 containing the light-emitting element 4 is located in the area where each pixel group 1 is located, which facilitates the subsequent movement of the droplets 5 containing the light-emitting elements 4 in the corresponding pixel group 1, thereby completing the assembly.

In some embodiments, as illustrated in FIGS. 9 and 10, each pixel group 1 in the transfer zone Z includes four first pixel units 11, and the four first pixel units 11 of the same pixel group 1 are arranged to form the two-dimensional array of two rows and two columns. The multiple pixel groups 1 in the transfer zone Z are arranged in the two-dimensional array. The first microfluidic pixels 2 of the same row of pixel groups 1 are located in the same row of first pixel units 11, and the first microfluidic pixels 2 of the same column of pixel groups 1 are located in the same column of first pixel units 11.

In some embodiments, the first microfluidic pixels 2 of all pixel groups 1 are located at the same position in pixel groups 1. That is, the first microfluidic pixels 2 of two adjacent pixel groups 1 in the same row are located in the first pixel unit 11 of the same row and the same column in the pixel group 1, and the first microfluidic pixels 2 of two adjacent pixel groups 1 in the same column are located in the first pixel unit 11 of the same row and the same column in the pixel group 1. As illustrated in FIG. 9, the four first pixel units 11 in each pixel group 1 form the two-dimensional array of two rows and two columns. The first microfluidic pixel 2 of each pixel group 1 is located in the pixel group 1 in the first row and the first column. All pixel groups 1 are arranged in the two-dimensional array, so that the first microfluidic pixels 2 of the same row of pixel groups 1 are located in the same row of first pixel units 11, and the first microfluidic pixels 2 of the same column of pixel groups 1 are located in the same column of first pixel units 11.

In some embodiments, as illustrated in FIG. 9, the first microfluidic pixels 2 of the same row of pixel groups 1 are all located in the first pixel unit 11 of the first row and the first column in the pixel group 1, and the first microfluidic pixels 2 of the same column of pixel groups 1 are all located in the first pixel unit 11 of the first row and the first column in the pixel group 1.

In some embodiments, as illustrated in FIG. 10, the first microfluidic pixels 2 of two adjacent pixel groups 1 in the same row are located in the first pixel unit 11 in the same row but different columns in the pixel group 1. The first microfluidic pixels 2 of two adjacent pixel groups 1 in the same column are located in the first pixel unit 11 in the same row and the same column in the pixel group 1. As illustrated in FIG. 10, the four first pixel units 11 in each pixel group 1 form the two-dimensional array of two rows and two columns. All pixel groups 1 are arranged in the two-dimensional array. The first microfluidic pixel 2 of the first pixel group 1 located in the first row is located in the first pixel unit 11 in the first row and the second column in the pixel group 1. The first microfluidic pixel 2 of the second pixel group 1 located in the first row is located in the first pixel unit 11 in the first row and the first column in the pixel group 1. The first microfluidic pixel 2 of the third pixel group 1 located in the first row is located in the first pixel unit 11 in the first row and the second column in the pixel group 1. The microfluidic pixels 2 of all pixel groups 1 in the first row are all located in the first pixel units 11 in the first row in the pixel group 1. Therefore, the first microfluidic pixels 2 of the pixel groups 1 in the same row are located in the first pixel units 11 in the same row. The first microfluidic pixels 2 of all pixel groups 1 located in the first column are located in the first pixel units 11 in the first row and the second column in the pixel group 1. The first microfluidic pixels 2 of all pixel groups 1 located in the second column are located in the first pixel units 11 in the first row and the first column in the pixel group 1. Therefore, the first microfluidic pixels 2 of all pixel groups 1 in the same column are located in the same column of first pixel units 11. It may avoid interference between the liquid droplets 5 containing the light-emitting elements 4 in different pixel groups 1 during the transportation of the liquid droplets 5 containing the light-emitting elements 4 into the pixel groups 1, which may affect the movement of the liquid droplets 5 containing the light-emitting elements 4, so that the transportation efficiency and the assembly efficiency of the liquid droplets 5 containing the light-emitting elements 4 may be greatly improved.

In some embodiments, as illustrated in FIG.S 9 and 10, the microfluidic transfer substrate 100 includes the transfer zone Z and the liquid droplet generation zone Y surrounding the transfer zone Z. The multiple pixel groups 1 are disposed in the transfer zone Z, and the liquid droplet generation zone Y has multiple second pixel units 6. All first pixel units 11 in the transfer zone Z and all second pixel units 6 in the liquid droplet generation zone Y are arranged in the two-dimensional array. The liquid droplet generation zone Y is configured to generate and transport the liquid droplets 5 containing the light-emitting elements 4 to the transfer zone Z. The liquid droplets 5 containing the light-emitting elements 4 are generated in the liquid droplet generation zone Y and then transported from the liquid droplet generation zone Y to the pixel groups 1 in the transfer zone Z. The liquid droplets 5 containing the light-emitting elements 4 move in the pixel groups 1, thereby completing the assembly of the light-emitting elements 4.

In some embodiments, as illustrated in FIGS. 9 and 10, multiple two-dimensional array distributed pixel groups 1 in the transfer zone Z collectively form a rectangular transfer zone Z. The liquid droplet generation zone Y is arranged in a rectangular ring shape and surrounds the transfer zone Z. The multiple second pixel units 6 in the liquid droplet generation zone Y correspond to the multiple first pixel units 11 in the multiple pixel groups 1 in the transfer zone Z, and all second pixel units 6 form the two-dimensional array together with the first pixel units 11. When the liquid droplet 5 containing the light-emitting element 4 generated in the liquid droplet generation zone Y is transported into the pixel group 1 in the transfer zone Z, the second pixel unit 6 may be configured as the transport channel for the liquid droplet 5, which is more convenient for driving the liquid droplet 5 containing the light-emitting element 4 to the position of the pixel group 1, shortening the transport path of the liquid droplet 5, improving the transport efficiency of the liquid droplet 5, and thereby improving the assembly efficiency of the light-emitting element 4.

In some embodiments, the liquid droplet generation zone Y may not have the second pixel unit 6, and the liquid droplet generation zone Y may be set only around the transfer zone Z. The liquid droplets 5 containing the light-emitting elements 4 are generated only in the liquid droplet generation zone Y. The liquid droplets 5 containing the light-emitting elements 4 generated in the liquid droplet generation zone Y may move in any direction or trajectory in the liquid droplet generation zone Y, as long as the liquid droplets 5 containing the light-emitting elements 4 may be transported from the liquid droplet generation zone Y to the transfer zone Z.

In some embodiments, the transfer zone Z may not be rectangular, and the liquid droplet generation zone Y may be set at any position in the transfer zone Z, that is, the liquid droplet generation zone Y may not be set around the transfer zone Z. In some embodiments, the liquid droplet generation zone Y may be set only on one or both sides of the transfer zone Z, as long as it may ensure that the liquid droplet generation zone Y may generate the liquid droplets 5 containing the light-emitting elements 4 and may be communicated with the transfer zone Z, so as to transport the liquid droplets 5 containing the light-emitting elements 4 to the transfer zone Z. Alternatively, the microfluidic transfer substrate 100 may not have the liquid droplet generation zone Y, that is, the microfluidic transfer substrate 100 may only have the transfer zone Z. Other structural components may be disposed to directly generate and transport the liquid droplets 5 containing the light-emitting elements 4 to the areas where different pixel groups 1 are located in the transfer zone Z. Alternatively, the multiple pixel groups 1 in the transfer zone Z may not be distributed in the two-dimensional array. In some embodiments, the multiple pixel groups 1 may be disposed at intervals or randomly distributed. The number of the first pixel units 11 in the pixel group 1 may also be any other number, such as three, five, or six, etc. The multiple first pixel units 11 in the pixel groups 1 may not be distributed in the two-dimensional array and may be designed as needed.

In some embodiments, the operation of controlling the liquid droplet 5 containing the light-emitting element 4 to move to the area where the corresponding pixel group 1 is located in the transfer zone Z, as described in the operation at block S22, includes:
controlling the liquid droplet 5 containing the light-emitting element 4 to move along the same row of first pixel units 11 without the first microfluidic pixels 2 to the area where the corresponding pixel group 1 is located, and stay on the second microfluidic pixel 3 of the same row of first pixel units 11 that are provided with the first microfluidic pixels 2.

In some embodiments, as illustrated in FIGS. 9 and 13, the four first pixel units 11 in the same pixel group 1 are arranged to form the two-dimensional array of two rows and two columns, and the multiple pixel groups 1 are arranged in the two-dimensional array. The liquid droplet 5 containing the light-emitting element 4 is controlled to move along the same row of first pixel units 11 without the first microfluidic pixels 2 to the area where the corresponding pixel group 1 is located, and stay on the second microfluidic pixel 3 of the same row of first pixel units 11 that are provided with the first microfluidic pixels 2. The liquid droplet 5 containing the light-emitting element 4 is controlled to move along the same row of first pixel units 11 without the first microfluidic pixels 2 to the area where the corresponding pixel group 1 is located, the same row of first pixel units 11 without the first microfluidic pixels 2 may serve as the transport channels for the liquid droplets 5 containing the light-emitting elements 4. The transport channel is unobstructed, ensuring that the liquid droplet 5 containing the light-emitting element 4 may be smoothly transported to each pixel group 1 in the transfer zone Z, avoiding interference between the motion trajectories of the liquid droplets 5 containing the light-emitting elements 4 in different pixel groups 1 when transporting the liquid droplets 5 containing the light-emitting elements 4. This interference may result in a decrease in the transport efficiency of the liquid droplet 5 containing the light-emitting element 4 or an inability to effectively transport the liquid droplet 5 containing the light-emitting element 4 to the pixel group 1. Furthermore, all liquid droplets 5 containing the light-emitting elements 4, in the areas where the pixel groups 1 are located, stay on the second microfluidic pixels 3 of the first pixel units 11 in the same row that are provided with the first microfluidic pixels 2. The stopping positions of the liquid droplets 5 containing the light-emitting elements 4 in all pixel groups 1 are consistent, which may facilitate the subsequent unified control of the liquid droplets 5 containing the light-emitting elements 4, enabling them to swing back and forth between the first microfluidic pixel 2 and three second microfluidic pixels 3 in the pixel group 1 or rotate around the center point Q. This is more conducive to improving the assembly efficiency and assembly yield of the light-emitting elements 4.

In some embodiments, the operation of controlling the liquid droplet 5 containing the light-emitting element 4 to move to the area where the corresponding pixel group 1 is located in the transfer zone Z, as described in the operation at block S22, includes:
controlling the liquid droplet 5 containing the light-emitting element 4 to move along the same column of first pixel units 11 without the first microfluidic pixels 2 to the area where the corresponding pixel group 1 is located, and stay on the second microfluidic pixel 3 of the same column of first pixel units 11 that are provided with the first microfluidic pixels 2.

In some embodiments, as illustrated in FIGS. 9 and 13, the four first pixel units 11 in the same pixel group 1 are arranged to form the two-dimensional array of two rows and two columns, the multiple pixel groups 1 are arranged in the two-dimensional array. The liquid droplet 5 containing the light-emitting element 4 is controlled to move along the same column of first pixel units 11 without the first microfluidic pixels 2 to the area where the corresponding pixel group 1 is located, and stay on the second microfluidic pixel 3 of the same column of first pixel units 11 that are provided with the first microfluidic pixels 2. Similarly, the above method may avoid interference between the motion trajectories of the liquid droplets 5 containing the light-emitting elements 4 in different pixel groups 1 when transporting the liquid droplets 5 containing the light-emitting elements 4. This interference may result in the decrease in the transport efficiency of the liquid droplet 5 containing the light-emitting element 4 or the inability to effectively transport the liquid droplet 5 containing the light-emitting element 4 to the pixel group 1. Furthermore, it may also facilitate the subsequent unified control of the liquid droplets 5 containing the light-emitting elements 4, enabling them to swing back and forth between the first microfluidic pixel 2 and three second microfluidic pixels 3 in the pixel group 1 or rotate around the center point Q. This is more conducive to improving the assembly efficiency and assembly yield of the light-emitting elements 4.

In some embodiments, the liquid droplet 5 containing the light-emitting element 4 may also be controlled to move along any other direction or trajectory to the area where the corresponding pixel group 1 is located, so that each area where the pixel group 1 is located has the liquid droplet 5 containing the light-emitting element 4. Alternatively, the microfluidic transfer substrate 100 may not have the liquid droplet generation zone Y, or specific structural components may be disposed to directly generate the liquid droplet 5 containing the light-emitting element 4 and directly transport the liquid droplet 5 containing the light-emitting element 4 to the area where each pixel group 1 is located. In some embodiments, the structural component may be located above the microfluidic transfer substrate 100 and may move between the areas corresponding to different pixel groups 1, so that the liquid droplets 5 containing the light-emitting elements 4 are directly dropped into different areas of the microfluidic transfer substrate 100, and each pixel group 1 has the liquid droplet 5 containing the light-emitting element 4.

At block S3, the transfer method of the light-emitting element 4 may include driving the liquid droplet 5 containing the light-emitting element 4 through the first pixel units 11 of the pixel group 1 to swing back and forth between the first microfluidic pixel 2 and the second microfluidic pixels 3, or rotate around the center point Q, so as to assemble the light-emitting element 4 into the assembly groove 21.

In some embodiments, the liquid droplet 5 containing the light-emitting element 4 in the pixel group 1 is driven by the first pixel units 11 of the pixel group 1 to swing back and forth between the first microfluidic pixel 2 and the second microfluidic pixel 3 in pixel group 1 or rotate around the center point Q, thereby enabling the light-emitting element 4 to be assembled into the assembly groove 21 of the first microfluidic pixel 2.

In some embodiments, the operation of driving the liquid droplet 5 containing the light-emitting element 4 through the first pixel units 11 of the pixel group 1 to swing back and forth between the first microfluidic pixel 2 and the second microfluidic pixels 3, or rotate around the center point Q, so as to assemble the light-emitting element 4 into the assembly groove 21, as described in the operation at block S3, includes:
simultaneously driving the liquid droplet 5 containing the light-emitting element 4 in the area where each pixel group 1 is located to swing back and forth between the first microfluidic pixel 2 and the second microfluidic pixel 3, or rotate around the center point Q.

In some embodiments, in the operation at block S2, the liquid droplet 5 containing the light-emitting element 4 has been formed in the area where each pixel group 1 of the microfluidic transfer substrate 100 is located. That is, the areas where all pixel groups 1 are located in the transfer zone Z already have the liquid droplets 5 containing the light-emitting elements 4. On this basis, the liquid droplets 5 containing the light-emitting elements 4 in the area where all pixel groups 1 are located in the transfer zone Z are simultaneously driven to swing back and forth between the first microfluidic pixel 2 and the second microfluidic pixels 3 in the corresponding pixel group 1 or rotate around the center point Q, so that the light-emitting element 4 of each of all pixel groups 1 may be assembled almost simultaneously into the assembly groove 21 of the corresponding first microfluidic pixel 2. By simultaneously controlling the movement of the liquid droplets 5 containing the light-emitting elements 4 of all pixel groups 1, it may effectively save assembly time and improve assembly efficiency, thereby improving the transfer efficiency of the light-emitting elements 4. Moreover, compared to sequentially driving the movement of the liquid droplets 5 containing the light-emitting elements 4 in the area where each pixel group 1 is located in the transfer zone Z, simultaneously driving the movement of all liquid droplets 5 containing the light-emitting elements 4 may simplify the driving method, so that the driving method is easier to operate.

In some embodiments, the liquid droplets 5 containing the light-emitting elements 4 may also be first formed in the area where some pixel groups 1 are located on the microfluidic transfer substrate 100. In some embodiments, the liquid droplets 5 containing the light-emitting elements 4 may be first transported from the liquid droplet generation zone Y to the areas where some pixel groups 1 are located on the microfluidic transfer substrate 100. Then, while driving the liquid droplets 5 containing the light-emitting elements 4 in these areas to swing back and forth between the first microfluidic pixel 2 and the second microfluidic pixel 3 in the corresponding pixel group 1 or rotate around the center point Q, so as to assemble the light-emitting elements 4 into the corresponding assembly grooves 21, the liquid droplets 5 containing the light-emitting elements 4 may be formed in the areas of the other pixel groups 1 on the microfluidic transfer substrate 100 where such liquid droplets 5 containing the light-emitting elements 4 have not yet been formed. Subsequently, the liquid droplets 5 containing the light-emitting elements 4 in these areas may be driven to swing back and forth between the first microfluidic pixel 2 and the second microfluidic pixels 3 in the corresponding pixel group 1 or rotate around the center point Q, so as to complete the assembly of the light-emitting elements 4 into the assembly grooves 21 on the microfluidic transfer substrate 100.

In some embodiments, the liquid droplet 5 containing the light-emitting element 4 may be transported to a single pixel group 1 of the microfluidic transfer substrate 100, and then the liquid droplet 5 containing the light-emitting element 4 is driven to swing back and forth between the first microfluidic pixel 2 and the second microfluidic pixels 3 in the pixel group 1 or rotate around the center point Q, so that the light-emitting element 4 is assembled into the assembly groove 21. Then, the liquid droplet 5 containing the light-emitting element 4 is sequentially transported to the next pixel group 1 of the microfluidic transfer substrate 100, and the liquid droplet 5 containing the light-emitting element 4 is driven to move, so as to complete the assembly of the light-emitting element 4, thereby completing the assembly of the light-emitting elements 4 in all assembly grooves 21 of the microfluidic transfer substrate 100. The specific driving method and driving timing of the liquid droplet 5 containing the light-emitting element 4 may be designed as needed, which is not limited in the present disclosure.

After the liquid droplet 5 containing the light-emitting element 4 moves between the first microfluidic pixel 2 and the second microfluidic pixels 3 in the pixel group 1 and the light-emitting element 4 is assembled into the corresponding assembly groove 21, the light-emitting element 4 no longer moves. The liquid droplet 5 is driven to continue moving on the microfluidic transfer substrate 100, so that the liquid droplet 5 returns from the transfer zone Z to the liquid droplet generation zone Y for subsequent reuse.

In some embodiments, after the operation at block S3, the structure shown in FIG. 17 may be obtained.

At block S4, the transfer method of the light-emitting element 4 may include attaching the microfluidic transfer substrate 100 to a driving backplane 700, so that the light-emitting element 4 in the assembly groove 21 is transferred onto the driving backplane 700.

In some embodiments, the driving backplane 700 is provided, as illustrated in FIG. 15. The microfluidic transfer substrate 100, which has been assembled with the light-emitting elements 4 after the operation at block S3, is attached to the driving backplane 700. In some embodiments, the microfluidic transfer substrate 100 is pressed onto the side of the driving backplane 700 with the driving electrodes 701, so that the light-emitting elements 4 in the assembly grooves 21 of the microfluidic transfer substrate 100 are transferred to the driving backplane 700, completing the transfer of the light-emitting elements 4. Then, the microfluidic transfer substrate 100 is separated from the driving backplane 700 for subsequent reuse of the microfluidic transfer substrate 100.

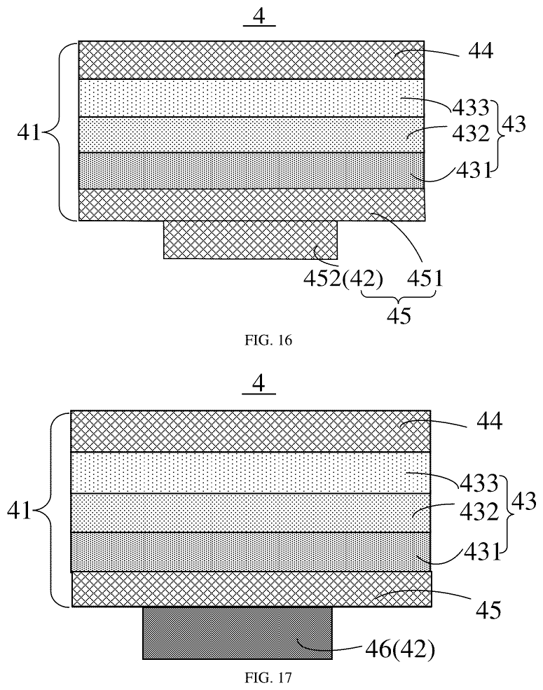

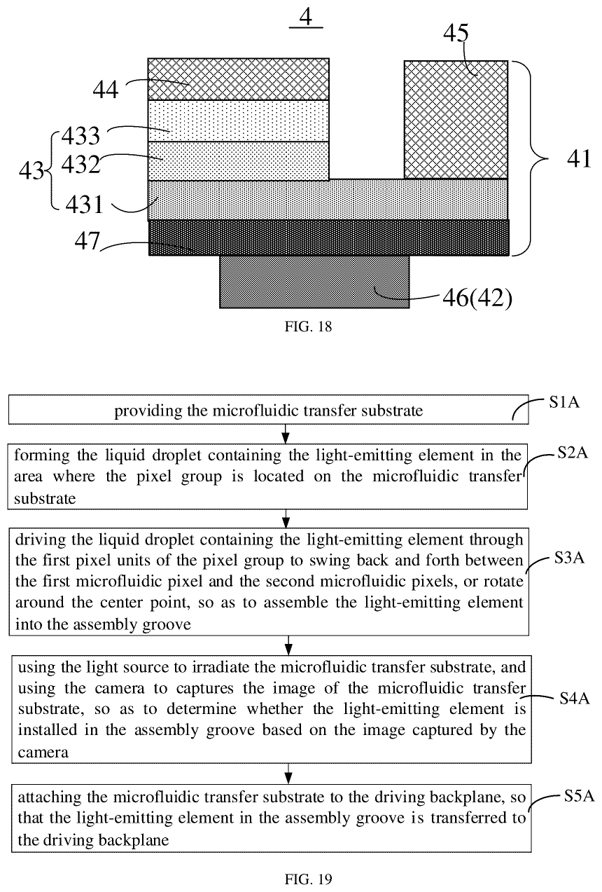

As illustrated in FIGS. 16 to 18, FIG. 16 is a structural schematic view of the light-emitting element in an embodiment of the present disclosure. FIG. 17 is a structural schematic view of the light-emitting element in another embodiment of the present disclosure. FIG. 18 is a structural schematic view of the light-emitting element in yet another embodiment of the present disclosure.

In some embodiments, the light-emitting element 4 is the light-emitting diode (LED), and the light-emitting diode includes the body part 41 and the protruding part 42 protruding from the body part 41. The width of the protruding part 42 is less than that of the assembly groove 21, and the width of the body part 41 is greater than that of the assembly groove 21. After assembling the light-emitting element 4 into the assembly groove 21, the protruding part 42 is inserted into the assembly groove 21, and the body part 41 protrudes from the assembly groove 21. The width of the protruding part 42 of the light-emitting element 4 is set to be less than that of the assembly groove 21, and the width of the body part 41 is set to be greater than that of the assembly groove 21. Therefore, the protruding part 42 may be matched with the assembly groove 21, and the assembly of the light-emitting element 4 in the assembly groove 21 may be achieved by inserting the protruding part 42 into the assembly groove 21, which is more conducive to improving the assembly efficiency. After assembling the protruding part 42 into the assembly groove 21, the light-emitting element 4 is not easily detached from the assembly groove 21, which is conducive to improving the assembly yield.

As illustrated in FIG. 16, in some embodiments, the light-emitting diode has a vertical structure. The light-emitting diode includes an epitaxial layer 43, a first electrode 44 located on one side of the epitaxial layer 43, and a second electrode 45 located on the opposite side of the epitaxial layer 43. The second electrode 45 includes a first conductive layer 451 covering the epitaxial layer 43 and a second conductive layer 452 that is located on the surface of the first conductive layer 451 away from the epitaxial layer 43. The second conductive layer 452 of the light-emitting diode forms the protruding part 42, and the remaining part forms the body part 41. That is, the second conductive layer 452 of the light-emitting diode protrudes from the first conductive layer 451, and the second conductive layer 452 is assembled in the assembly groove 21 of the first microfluidic pixel 2.

As illustrated in FIG. 16, in some embodiments, the epitaxial layer 43 includes an electron transport layer 431, a quantum well layer 432, and a hole transport layer 433 stacked in sequence. The first electrode 44 is a P electrode, and the second electrode 45 is an n electrode. In some embodiments, the first electrode 44 may also be the n electrode and the second electrode 45 may be the P electrode.

As illustrated in FIG. 17, in some embodiments, the light-emitting diode has the vertical structure. The light-emitting diode includes the epitaxial layer 43, the first electrode 44 located on one side of the epitaxial layer 43, the second electrode 45 located on the opposite side of the epitaxial layer 43, and a photoresist layer 46 that is located on the surface of the second electrode 45 away from the epitaxial layer 43. The photoresist layer 46 of the light-emitting diode forms the protruding part 42, and the remaining part forms the body part 41. That is, the photoresist layer 46 of the light-emitting diode is assembled into the assembly groove 21 of the first microfluidic pixel 2.

As illustrated in FIG. 17, in some embodiments, the epitaxial layer 43 includes the electron transport layer 431, the quantum well layer 432, and the hole transport layer 433 stacked in sequence. The first electrode 44 is the P electrode, and the second electrode 45 is the n electrode. In some embodiments, the first electrode 44 may also be the n-electrode and the second electrode 45 may be the P-electrode.

In some embodiments, after the operation at block S4 of attaching the microfluidic transfer substrate 100 to the driving backplane 700, so that the light-emitting element 4 in the assembly groove 21 is transferred onto the driving backplane 700, the transfer method of the light-emitting element 4 may further include:
removing the photoresist layer 46.

In some embodiments, after attaching the microfluidic transfer substrate 100 to the driving backplane 700, so that the light-emitting elements 4 in the assembly grooves 21 are transferred onto the driving backplane 700, due to the presence of the photoresist layer 46 on the surface of the second electrode 45 away from the epitaxial layer 43, in order not to affect the normal use of the light-emitting diode, it is necessary to remove the photoresist layer 46 located on the surface of the second electrode 45 away from the epitaxial layer 43, thereby exposing the second electrode 45.

As illustrated in FIG. 18, in some embodiments, the light-emitting diode has a lateral structure. The light-emitting diode includes a base 47, the epitaxial layer 43 disposed on the base 47, the first electrode 44 and the second electrode 45 that are located on the epitaxial layer 43, and the photoresist layer 46 that is located on the surface of the base 47 away from the epitaxial layer 43. The photoresist layer 46 of the light-emitting diode forms the protruding part 42, and the remaining part forms the body part 41. That is, the photoresist layer 46 of the light-emitting diode is assembled into the assembly groove 21 of the first microfluidic pixel 2.

As illustrated in FIG. 18, in some embodiments, the epitaxial layer 43 includes the electron transport layer 431, the quantum well layer 432, and the hole transport layer 433. The quantum well layer 432 and the hole transport layer 433 are stacked on the surface of the electron transport layer 431 away from the base 47. The first electrode 44 is disposed on and covers the surface of the hole transport layer 433, and the second electrode 45 is disposed on the surface of the electron transport layer 431 away from the base 47. The second electrode 45 is spaced apart from the quantum well layer 432, the hole transport layer 433, and the first electrode 44. In some embodiments, the first electrode 44 is the P electrode, and the second electrode 45 is the n electrode. In some embodiments, the first electrode 44 may also be the n electrode and the second electrode 45 may be the P electrode.

In some embodiments, after the operation at block S4 of attaching the microfluidic transfer substrate 100 to the driving backplane 700, so that the light-emitting element 4 in the assembly groove 21 is transferred onto the driving backplane 700, the transfer method of the light-emitting element 4 may further include:
removing the photoresist layer 46.

In some embodiments, after attaching the microfluidic transfer substrate 100 to the driving backplane 700, so that the light-emitting elements 4 in the assembly grooves 21 are transferred onto the driving backplane 700, due to the lateral structure of the light-emitting diode, the photoresist layer 46 is located on the surface of the base 47 away from the epitaxial layer 43, in order to avoid affecting the normal use of the light-emitting diode, it is necessary to remove the photoresist layer 46 located on the surface of the base 47 away from the epitaxial layer 43, thereby exposing the base 47.

In some embodiments, the light-emitting element 4 may also be a micro light-emitting diode, and the protruding part 42 of the light-emitting element 4 may also be formed by other structures or methods. Alternatively, the light-emitting element 4 may not have the protruding part 42 and only include the body part 41, and the body part 41 of the light-emitting element 4 may be directly assembled into the assembly groove 21 of the first microfluidic pixel 2, which may be designed as needed.

The mass transfer of the light-emitting elements 4 may be achieved by the transfer method of the light-emitting element 4 in some embodiments, which may solve the problem that it is difficult to achieve mass transfer of the light-emitting elements 4 in related art.

As illustrated in FIG. 19, FIG. 19 is a flowchart of a method for transferring the light-emitting elements in a second embodiment of the present disclosure.

As illustrated in FIG. 19, the present disclosure further provides another method for transferring the light-emitting elements 4. In some embodiments, the method for transferring the light-emitting elements 4 includes the following operations.

At block S1A, the method for transferring the light-emitting elements 4 may include providing the microfluidic transfer substrate 100.

In some embodiments, the specific operations of the operation at block S1 in the method for transferring the light-emitting elements 4 in the first embodiment are the same as the specific operations of the operation at block SIA in the method for transferring the light-emitting elements 4 in the second embodiment, and they may achieve the same or similar technical effects, which may not be repeated here.

At block S2A, the method for transferring the light-emitting elements 4 may include forming the liquid droplet 5 containing the light-emitting element 4 in the area where the pixel group 1 is located on the microfluidic transfer substrate 100.

In some embodiments, the specific operations of the operation at block S2 in the method for transferring the light-emitting elements 4 in the first embodiment are the same as the specific operations of the operation at block S2A in the method for transferring the light-emitting elements 4 in the second embodiment, and they may achieve the same or similar technical effects, which may not be repeated here.

At block S3A, the method for transferring the light-emitting elements 4 may include driving the liquid droplet 5 containing the light-emitting element 4 through the first pixel units 11 of the pixel group 1 to swing back and forth between the first microfluidic pixel 2 and the second microfluidic pixels 3, or rotate around the center point Q, so as to assemble the light-emitting element 4 into the assembly groove 21.

In some embodiments, the specific operations of the operation at block S3 in the method for transferring the light-emitting elements 4 in the first embodiment are the same as the specific operations of the operation at block S3A in the method for transferring the light-emitting elements 4 in the second embodiment, and they may achieve the same or similar technical effects, which may not be repeated here.

At block S4A, the method for transferring the light-emitting elements 4 may include using the light source 400 to irradiate the microfluidic transfer substrate 100, and using the camera 500 to captures the image of the microfluidic transfer substrate 100, so as to determine whether the light-emitting element 4 is assembled in the assembly groove 21 based on the image captured by the camera 500.

In some embodiments, different from the method for transferring the light-emitting elements 4 in the first embodiment, in the second embodiment, after assembling the light-emitting element 4 into the assembly groove 21 of the microfluidic transfer substrate 100, it is also necessary to detect the assembly yield of the light-emitting element 4 on the microfluidic transfer substrate 100. In some embodiments, the planarization layer 15 of the microfluidic transfer substrate 100 is the opaque layer. The microfluidic transfer substrate 100 only transmits light at the position of the assembly groove 21, and does not transmit light at other positions. The light source 400 may be configured to irradiate the microfluidic transfer substrate 100, so as to determine whether the light-emitting element 4 is assembled in the assembly groove 21.

In some embodiments, when the assembly groove 21 of the first microfluidic pixel 2 of the microfluidic transfer substrate 100 is provided with the light-emitting element 4 and the light source 400 irradiates the microfluidic transfer substrate 100, the light passing through the assembly groove 21 may be greatly reduced or even the position of the assembly groove 21 may no longer be transparent (no longer transmit light). When some assembly grooves 21 are not provided with the light-emitting elements 4 and the light source 400 irradiates the microfluidic transfer substrate 100, the light passing through the position of the assembly groove 21 without the light-emitting element 4 is still sufficient. The camera 500 captures the image of the microfluidic transfer substrate 100 under the irradiation of the light source 400. Based on the image captured by the camera 500, it may be determined whether the light-emitting element 4 is assembled in the assembly groove 21. In some embodiments, in the case where the light passes through the assembly groove 21 is significantly reduced or the assembly groove 21 does not transmit light, it may be determined that the light-emitting element 4 has been assembled in the assembly groove 21. In the case where the light passing through the assembly groove 21 is still sufficient, it may be determined that the light-emitting element 4 is not assembled in the assembly groove 21.

In some embodiments, the number of the assembly grooves 21 on the microfluidic transfer substrate 100 that have been provided with the light-emitting elements 4, and the number of the assembly grooves 21 on the microfluidic transfer substrate 100 that have not been provided with the light-emitting elements 4, may be determined based on the images captured by the camera 500. The assembly yield of the light-emitting elements 4 on the microfluidic transfer substrate 100 may be calculated. The actual assembly yield of the light-emitting elements 4 on the microfluidic transfer substrate 100 may be compared with the ideal assembly yield, so as to determine whether the assembly yield of the microfluidic transfer substrate 100 meets the standard. In some embodiments, the ideal assembly yield is 99.9%. In the case where the actual assembly yield reaches 99.9%, it indicates that the microfluidic transfer substrate 100 that is provided with the light-emitting elements 4 is qualified. In the case where the actual assembly yield does not reach 99.9%, it indicates that the microfluidic transfer substrate 100 that is provided with the light-emitting elements 4 is unqualified, facilitating subsequent processing.

At block S5A, the method for transferring the light-emitting elements 4 may include attaching the microfluidic transfer substrate 100 to the driving backplane 700, so that the light-emitting element 4 in the assembly groove 21 is transferred to the driving backplane 700.

In some embodiments, the specific operations of the operation at block S4 in the method for transferring the light-emitting elements 4 in the first embodiment are the same as the specific operations of the operation at block S5A in the method for transferring the light-emitting elements 4 in the second embodiment, and they may achieve the same or similar technical effects, which may not be repeated here.

By the transfer method of the light-emitting element 4 provided in some embodiments, mass transfer of the light-emitting elements 4 may be achieved, which may solve the problem that it is difficult to achieve mass transfer of the light-emitting elements 4 in related art. Furthermore, in some embodiments, each light-emitting element 4 is independent of each other and assembled separately. Therefore, the light-emitting elements 4 of different colors and different sizes are simultaneously assembled, meeting diverse usage requirements.

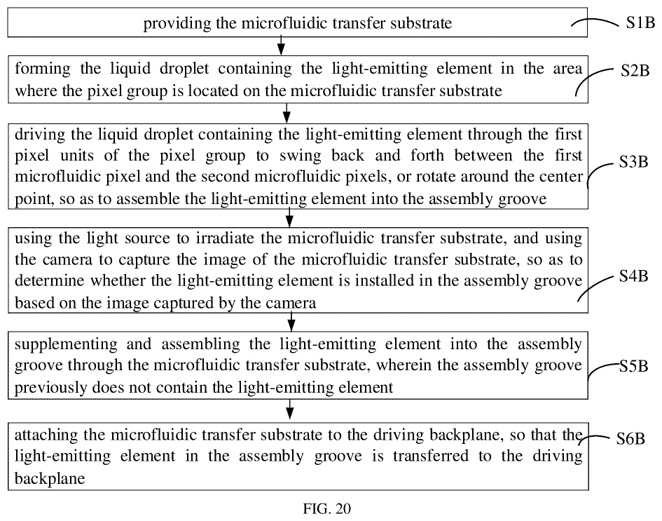

As illustrated in FIG. 20, FIG. 20 is a flowchart of a method for transferring the light-emitting elements in a third embodiment of the present disclosure.

As illustrated in FIG. 20, the present disclosure further provides yet another method for transferring the light-emitting elements 4. In some embodiments, the method for transferring the light-emitting elements 4 includes the following operations.

At block S1B, the method for transferring the light-emitting elements 4 may include providing the microfluidic transfer substrate 100.

In some embodiments, the specific operations of the operation at block S1 in the method for transferring the light-emitting elements 4 in the first embodiment are the same as the specific operations of the operation at block SIB in the method for transferring the light-emitting elements 4 in the third embodiment, and they may achieve the same or similar technical effects, which may not be repeated here.

At block S2B, the method for transferring the light-emitting elements 4 may include forming the liquid droplet 5 containing the light-emitting element 4 in the area where the pixel group 1 is located on the microfluidic transfer substrate 100.

In some embodiments, the specific operations of the operation at block S2 in the method for transferring the light-emitting elements 4 in the first embodiment are the same as the specific operations of the operation at block S2B in the method for transferring the light-emitting elements 4 in the third embodiment, and they may achieve the same or similar technical effects, which may not be repeated here.

At block S3B, the method for transferring the light-emitting elements 4 may include driving the liquid droplet 5 containing the light-emitting element 4 through the first pixel units 11 of the pixel group 1 to swing back and forth between the first microfluidic pixel 2 and the second microfluidic pixels 3, or rotate around the center point Q, so as to assemble the light-emitting element 4 into the assembly groove 21.

In some embodiments, the specific operations of the operation at block S3 in the method for transferring the light-emitting elements 4 in the first embodiment are the same as the specific operations of the operation at block S3B in the method for transferring the light-emitting elements 4 in the third embodiment, and they may achieve the same or similar technical effects, which may not be repeated here.

At block S4B, the method for transferring the light-emitting elements 4 may include using the light source 400 to irradiate the microfluidic transfer substrate 100, and using the camera 500 to capture the image of the microfluidic transfer substrate 100, so as to determine whether the light-emitting element 4 is assembled in the assembly groove 21 based on the image captured by the camera 500.

In some embodiments, the specific operations of the operation at block S4A in the method for transferring the light-emitting elements 4 in the second embodiment are the same as the specific operations of the operation at block S4B in the method for transferring the light-emitting elements 4 in the third embodiment, and they may achieve the same or similar technical effects, which may not be repeated here.

At block S5B, the method for transferring the light-emitting elements 4 may include supplementing and assembling the light-emitting element 4 into the assembly groove 21 through the microfluidic transfer substrate 100, wherein the assembly groove 21 previously does not contain the light-emitting element 4.

In some embodiments, after the operation at block S4B of using the light source 400 to irradiate the microfluidic transfer substrate 100 and using the camera 500 to capture the image of the microfluidic transfer substrate 100, so as to determine whether the light-emitting element 4 is assembled in the assembly groove 21 based on the image captured by the camera 500, the light-emitting element 4 is re-assembled in the assembly groove 21 that is not provided with the light-emitting element 4, and the designated position is subjected to secondary assembly. This operation may ensure the assembly quantity of the light-emitting elements 4 on the microfluidic transfer substrate 100, which is more conducive to improving the transfer efficiency of the light-emitting elements 4.

In some embodiments, when the actual assembly yield does not reach the ideal assembly yield, the assembly groove 21 without the light-emitting element 4 may be re-assembled with the light-emitting element 4, so as to achieve the ideal assembly yield. Alternatively, without calculating the actual assembly yield, all assembly grooves 21 on the microfluidic transfer substrate 100 without the light-emitting elements 4 may be directly re-assembled with the light-emitting elements 4 until all assembly grooves 21 on the microfluidic transfer substrate 100 are provided with the light-emitting elements 4, ensuring the assembly quantity of the light-emitting elements 4 on the microfluidic transfer substrate 100. It facilitates the subsequent transfer of a large amount of light-emitting elements 4 from the microfluidic transfer substrate 100 to the driving backplane 700, improves transfer efficiency, and achieves mass transfer of the light-emitting elements 4, thereby improving the light-emitting efficiency of the driving backplane 700 after the light-emitting elements 4 are transferred.

In some embodiments, the method and operations for re-supplementing the light-emitting element 4 in the assembly groove 21 that has not been provided with the light-emitting element 4 may refer to the operations and methods described above for the first assembly of the light-emitting element 4 in the assembly groove 21 of the first microfluidic pixel 2 of the pixel group 1, which may not be repeated here.

At block S6B, the method for transferring the light-emitting elements 4 may include attaching the microfluidic transfer substrate 100 to the driving backplane 700, so that the light-emitting element 4 in the assembly groove 21 is transferred to the driving backplane 700.

In some embodiments, the specific operations of the operation at block S4 in the method for transferring the light-emitting elements 4 in the first embodiment are the same as the specific operations of the operation at block S6B in the method for transferring the light-emitting elements 4 in the third embodiment, and they may achieve the same or similar technical effects, which may not be repeated here.

By the transfer method of the light-emitting element 4 in some embodiments, mass transfer of the light-emitting elements 4 may be achieved, which may solve the problem that it is difficult to achieve mass transfer of the light-emitting elements 4 in related art.

Different from the related art, the effects of the present disclosure are as follows. The present disclosure provides a microfluidic transfer substrate, a microfluidic transfer device, and a microfluidic transfer apparatus. The microfluidic transfer substrate includes a plurality of pixel groups. Each pixel group includes at least three first pixel units, and the at least three first pixel units of each pixel group are arranged around a center point; one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove; and each first pixel unit includes a thin film transistor, a microfluidic electrode layer, and a hydrophobic layer. By the above settings, it is easier to assemble the light-emitting element into the assembly groove of the first microfluidic pixel on the microfluidic transfer substrate, and it is more convenient to use the microfluidic transfer substrate for mass transfer of the light-emitting elements, which may solve the problem that it is difficult to achieve mass transfer of the light-emitting elements in related art and achieve mass transfer of the light-emitting elements.

The above descriptions are only some embodiments of the present disclosure, and are not intended to limit the protection scope of the present disclosure. Any equivalent structure or equivalent flow transformation made by using the contents and the accompanying drawings of the present disclosure, or directly or indirectly applied to other related technical fields, is included in the protection scope of the present disclosure.

1. A microfluidic transfer substrate, comprising:
a plurality of pixel groups;
wherein each pixel group comprises at least three first pixel units, and the at least three first pixel units of each pixel group are arranged around a center point; one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove; and each first pixel unit comprises a thin film transistor, a microfluidic electrode layer, and a hydrophobic layer.

2. The microfluidic transfer substrate according to claim 1, wherein
each pixel group comprises four first pixel units, and the four first pixel units of the same pixel group are arranged to form a two-dimensional array of two rows and two columns.

3. The microfluidic transfer substrate according to claim 2, wherein
the plurality of pixel groups are arranged in the two-dimensional array, and the first microfluidic pixels of the plurality of pixel groups are located at the same position in the pixel groups.

4. The microfluidic transfer substrate according to claim 1, wherein
the microfluidic transfer substrate is configured to only transmit light at a position of the assembly groove.

5. The microfluidic transfer substrate according to claim 4, wherein
each first pixel unit comprises a substrate, the thin film transistor, a first insulation layer, a planarization layer, the microfluidic electrode layer, a second insulation layer, and the hydrophobic layer arranged in sequence;
wherein the planarization layer is an opaque layer, the assembly groove penetrates through the opaque layer, and the microfluidic electrode layer is a transparent conductive layer or defines an opening corresponding to the assembly groove; or the microfluidic electrode layer is an opaque layer and defines the opening corresponding to the assembly groove.

6. The microfluidic transfer substrate according to claim 5, wherein
the planarization layer is a black material layer, the black material layer defines a through hole to expose a part of the first insulation layer, thereby forming the assembly groove;
the microfluidic electrode layer, the second insulation layer, and the hydrophobic layer all cover a bottom surface and a side surface of the assembly groove; or the microfluidic electrode layer is only disposed on a surface of the black material layer away from the substrate and defines the opening corresponding to the assembly groove, and both the second insulation layer and the hydrophobic layer cover the bottom surface and the side surface of the assembly groove.

7. The microfluidic transfer substrate according to claim 1, wherein
the microfluidic transfer substrate includes a transfer zone and a liquid droplet generation zone surrounding the transfer zone, the plurality of pixel groups are disposed in the transfer area, and the liquid droplet generation zone is configured to generate and transport a liquid droplet containing a light-emitting element to the transfer zone.

8. The microfluidic transfer substrate according to claim 7, wherein
a plurality of second pixel units are disposed in the liquid droplet generation zone, the plurality of second pixel units have the same structure as the second microfluidic pixel, and all first pixel units in the transfer area and all second pixel units in the liquid droplet generation area are arranged in a two-dimensional array.

9. A microfluidic transfer device, comprising:
a microfluidic transfer substrate, comprising:
a plurality of pixel groups;
wherein each pixel group comprises at least three first pixel units, and the at least three first pixel units of each pixel group are arranged around a center point; one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove; and each first pixel unit comprises a thin film transistor, a microfluidic electrode layer, and a hydrophobic layer; and
a microfluidic control circuit, electrically connected to the microfluidic transfer substrate;
wherein the microfluidic control circuit is configured to drive a liquid droplet containing a light-emitting element through the first pixel units of the pixel group to swing back and forth between the first microfluidic pixel and the second microfluidic pixels, or rotate around the center point, so as to assemble the light-emitting element into the assembly groove.

10. The microfluidic transfer device according to claim 9, wherein
each pixel group comprises four first pixel units, and the four first pixel units of the same pixel group are arranged to form a two-dimensional array of two rows and two columns.

11. The microfluidic transfer device according to claim 10, wherein
the plurality of pixel groups are arranged in the two-dimensional array, and the first microfluidic pixels of the plurality of pixel groups are located at the same position in the pixel groups.

12. The microfluidic transfer device according to claim 9, wherein
the microfluidic transfer substrate is configured to only transmit light at a position of the assembly groove.

13. The microfluidic transfer device according to claim 12, wherein
each first pixel unit comprises a substrate, the thin film transistor, a first insulation layer, a planarization layer, the microfluidic electrode layer, a second insulation layer, and the hydrophobic layer arranged in sequence;
wherein the planarization layer is an opaque layer, the assembly groove penetrates through the opaque layer, and the microfluidic electrode layer is a transparent conductive layer or defines an opening corresponding to the assembly groove; or
the microfluidic electrode layer is an opaque layer and defines the opening corresponding to the assembly groove.

14. The microfluidic transfer device according to claim 13, wherein
the planarization layer is a black material layer, the black material layer defines a through hole to expose a part of the first insulation layer, thereby forming the assembly groove;
the microfluidic electrode layer, the second insulation layer, and the hydrophobic layer all cover a bottom surface and a side surface of the assembly groove; or the microfluidic electrode layer is only disposed on a surface of the black material layer away from the substrate and defines the opening corresponding to the assembly groove, and both the second insulation layer and the hydrophobic layer cover the bottom surface and the side surface of the assembly groove.

15. The microfluidic transfer device according to claim 9, wherein
the microfluidic transfer substrate includes a transfer zone and a liquid droplet generation zone surrounding the transfer zone, the plurality of pixel groups are disposed in the transfer area, and the liquid droplet generation zone is configured to generate and transport a liquid droplet containing a light-emitting element to the transfer zone.

16. The microfluidic transfer device according to claim 15, wherein
a plurality of second pixel units are disposed in the liquid droplet generation zone, the plurality of second pixel units have the same structure as the second microfluidic pixel, and all first pixel units in the transfer area and all second pixel units in the liquid droplet generation area are arranged in a two-dimensional array.

17. A microfluidic transfer apparatus, comprising:
a microfluidic transfer device, comprising:
a microfluidic transfer substrate, comprising:
a plurality of pixel groups;
wherein each pixel group comprises at least three first pixel units, and the at least three first pixel units of each pixel group are arranged around a center point; one first pixel unit of each pixel group serves as a first microfluidic pixel and a surface of the first microfluidic pixel defines an assembly groove, and the other first pixel units of each pixel group serve as second microfluidic pixels and a surface of each second microfluidic pixel is free of the assembly groove; and each first pixel unit comprises a thin film transistor, a microfluidic electrode layer, and a hydrophobic layer; and
a microfluidic control circuit, electrically connected to the microfluidic transfer substrate;
wherein the microfluidic control circuit is configured to drive a liquid droplet containing a light-emitting element through the first pixel units of the pixel group to swing back and forth between the first microfluidic pixel and the second microfluidic pixels, or rotate around the center point, so as to assemble the light-emitting element into the assembly groove;
a light source, disposed on one side of the microfluidic transfer substrate and electrically connected to the microfluidic control circuit; and
a camera, disposed on the other side of the microfluidic transfer substrate and electrically connected to the microfluidic control circuit;
wherein the microfluidic control circuit is further configured to control the light source to emit light and irradiate the microfluidic transfer substrate, control the camera to capture an image of the microfluidic transfer substrate, and determine whether the light-emitting element is assembled in the assembly groove based on the image captured by the camera.

18. The microfluidic transfer apparatus according to claim 17, wherein
each pixel group comprises four first pixel units, and the four first pixel units of the same pixel group are arranged to form a two-dimensional array of two rows and two columns.

19. The microfluidic transfer apparatus according to claim 18, wherein
the plurality of pixel groups are arranged in the two-dimensional array, and the first microfluidic pixels of the plurality of pixel groups are located at the same position in the pixel groups.

20. The microfluidic transfer apparatus according to claim 17, wherein
the microfluidic transfer substrate is configured to only transmit light at a position of the assembly groove.
